(19) United States
(12) Patent Application Publication
(10) Pub. No.: US 2018/0224552 A1
(43) Pub. Date: Aug. 9, 2018

(54) COMPRESSED-SENSING ULTRAFAST PHOTOGRAPHY (CUP)

(71) Applicant: Washington University, St. Louis, MO (US)

(72) Inventors: Lihong Wang, St. Louis, MO (US); Jinyang Liang, St. Louis, MO (US); Liang Gao, St. Louis, MO (US)

(21) Appl. No.: 15/505,853

(22) PCT Filed: Sep. 30, 2015
(86) PCT No.: PCT/US2015/053326

§ 371 Date: Feb. 22, 2017

Related U.S. Application Data
(60) Provisional application No. 62/057,830, filed on Sep. 30, 2014.

(51) Int. Cl. G01S 17/89; G01S 17/10; H03M 7/30; H04N 19/593; H04N 19/503

(52) U.S. Cl. CPC G01S 17/89; G01S 17/10; H04N 19/503; H04N 19/593; H03M 7/3062

(57) ABSTRACT

A system and method for compressed-sensing ultrafast photography for two-dimensional dynamic imaging is disclosed. The system and method may capture non-repetitive time-evolving events at up to about 100 billion frames per second. In an aspect, a digital micromirror device (DMD) may be added as the spatial encoding module. By using the DMD and applying the CUP reconstruction algorithm, a conventional 1D streak camera may be transformed to a 2D ultrafast imaging device. The resultant system may capture a single, non-repetitive event at up to 100 billion frames per second with appreciable sequence depths (up to about 350 frames per acquisition). In another aspect, a dichroic mirror may be used to separate signals into two color channels, and may further expand CUP's functionality into the realm of four-dimensional x, y, k, t ultrafast imaging, maximizing the information content that may be simultaneously acquired from a single instrument. On the basis of compressed sensing (CS), CUP may encode the spatial domain with a pseudo-random binary pattern, followed by a shearing operation in the temporal domain, performed using a streak camera with a fully opened entrance slit. This encoded, sheared three-dimensional (3D) x, y, t scene may then be measured by a 2D detector array, such as a CCD, within a single snapshot. The image reconstruction process follows a strategy similar to CS-based image restoration—iteratively estimating a solution that minimizes an objective function. However, unlike CS-based image restoration algorithms, which target the reconstruction of a 2D x, y image, CUP reconstruction recovers a 3D x, y, t movie by applying regularization over both the spatial domain and the temporal domain.

### CROSS-REFERENCE TO RELATED APPLICATIONS

This application claims priority to U.S. Provisional Patent Application No. 62/057,830 filed on Sep. 30, 2014, which is hereby incorporated by reference in its entirety.

### STATEMENT REGARDING FEDERALLY SPONSORED RESEARCH & DEVELOPMENT

This invention was made with government support under grants DPI EB016986 and R01CA186567, both awarded by the U.S. National Institutes of Health. The U.S. government may have certain rights in this invention.

### FIELD OF THE INVENTION

The present invention relates to systems and methods of compressed-sensing ultrafast photography (CUP). In particular, the present invention relates to about 100 billion frames per second dynamic imaging of non-repetitive events.

### BACKGROUND

Capturing transient scenes at a high imaging speed has been pursued by photographers for centuries, tracing back to Muybridge's 1878 recording of a horse in motion and Mach's 1887 photography of a supersonic bullet. However, not until the late 20^{th} century were breakthroughs achieved in demonstrating ultra-high speed imaging (>100 thousand, or 10⁵, frames per second). In particular, the introduction of electronic imaging sensors, such as the charge-coupled device (CCD) and complementary metal-oxide-semiconductor (CMOS), revolutionized high-speed photography, enabling acquisition rates up to ten million (10⁷) frames per second. Despite the widespread impact of these sensors, further increasing frame rates of imaging systems using CCD or CMOS is fundamentally limited by their on-chip storage and electronic readout speed.

3D imaging techniques have been used in many applications, including remote sensing, biology, and entertainment, as well as in safety and national security applications such as biometrics, under-vehicle inspection, and battlefield evaluation. The suitability of 3D imaging for these diverse applications is enhanced if the 3D images may be captured and transmitted to users in a secure and fast manner. Photons scattered from the object to be imaged carry a variety of tags, such as emittance angle and time-of-flight (ToF), which convey 3D surface information used in various 3D imaging methods, including structured-illumination, holography, streak imaging, integral imaging, multiple camera or multiple single-pixel detector photogrammetry, and time of flight (ToF) detection. Holography is one 3D imaging method that enables an intrinsic holography-based encryption of the 3D images that makes use of a pseudo-random phase or amplitude mask used to obtain the 3D image as a decryption key for reconstructing images of the 3D object. However, the holographic imaging method is sensitive to motion of the object due to relatively long exposure times, which may degrade image quality.

ToF is another 3D imaging method that makes use of the ToF of a light signal from the object to a detector to quantify the distances of various regions of the object for use in reconstructing a 3D image of the object. Some ToF imaging systems acquire 3D images using multiple ToF measurements, which limits suitability of these systems for imaging fast-moving 3D objects. In other ToF imaging systems, single-shot ToF detection has been incorporated to mitigate motion distortion in 3D images. However, existing single-shot ToF 3D imaging systems are characterized by relatively low imaging speeds of up to 30 Hz and relatively low image resolution on the order of about 10 cm. In addition, existing ToF 3D imaging systems lack the intrinsic encryption capability associated with holography.

### SUMMARY

Provided herein is a compressed-sensing ultrafast photography system to obtain a series of final recorded images of an object. The system may include a spatial encoding module to receive a first series of object images and to produce a second series of spatially encoded images, each spatially encoded image of the second series comprising one object image of the first series superimposed with a pseudo-random binary spatial pattern and a temporal encoding module operatively coupled to the spatial encoding module, the temporal encoding module configured to receive an entire field of view of each spatially encoded image of the second series, to deflect each spatially encoded image by a temporal deflection distance proportional to time-of-arrival, and to record each deflected image as a third series of spatially/temporally encoded images, each spatially/temporally encoded image of the third series comprising an object image superimposed with a pseudo-random binary spatial pattern and deflected by the temporal deflection distance.

Further provided herein is a method of obtaining a series of final recorded images of an object using a compressed-sensing ultrafast photography system at a rate of up to one billion frames per second. The method may include collecting a first series of object images, superimposing a pseudo-random binary spatial pattern onto each object image of the first series to produce a second series of spatially encoded images, deflecting each spatially encoded image of the second series by a temporal deflection distance proportional to a time-of-arrival of each spatially encoded image, recording each deflected spatially encoded image as a third series of spatially/temporally encoded images, and reconstructing a fourth series of final object images by processing each spatially/temporally encoded image of the third series according to an image reconstruction algorithm.

Additionally provided herein is a compressed-sensing ultrafast photography system to obtain a series of final recorded images of an object. The system may include an optical module including a camera lens operatively coupled to a beam splitter, a beam splitter operatively coupled to a temporal encoding module and operatively coupled to a tube lens, the tube lens operatively coupled to an objective, the objective operatively coupled to a spatial encoding module, the spatial encoding module configured to receive the first series of object images from the objective and to transfer a second series of spatially encoded images to the objective, each spatially encoded image of the second series comprising one object image of the first series superimposed with a pseudo-random binary spatial pattern, and a temporal encoding module operatively coupled to the beam splitter. The temporal encoding module may be configured to receive an entire field of view of each spatially encoded image of the second series via the objective, the tube lens, and the beam splitter, to deflect each spatially encoded image by a temporal deflection distance proportional to time-of-arrival, and to record each deflected image as a third series of spatially/temporally encoded images, each spatially/temporally encoded image of the third series comprising an object image superimposed with a pseudo-random binary spatial pattern and deflected by the temporal deflection distance.

Also provided is a time of flight compressed-sensing ultrafast 3D imaging system to obtain a series of 3D images of an outer surface of an object. The system includes: a spatial encoding module to receive a first series of object images and to produce a second series of spatially encoded images, each spatially encoded image of the second series including one object image of the first series superimposed with a pseudo-random binary spatial pattern; a temporal encoding module operatively coupled to the spatial encoding module, the temporal encoding module configured to receive an entire field of view of each spatially encoded image of the second series, to deflect each spatially encoded image by a temporal deflection distance proportional to time-of-arrival, and to record each deflected image as a third series of spatially/temporally encoded images, each spatially/temporally encoded image of the third series including an object image superimposed with a pseudo-random binary spatial pattern and deflected by the temporal deflection distance; an illumination source including a pulsed laser operatively coupled to the temporal encoding module. The illumination source delivers a laser pulse to illuminate the object and records a pulse delivery time, and an elapsed time between the pulse delivery time and the time of arrival is the round-trip time of flight. The system further includes a reference camera to record a 2D reference image of the object, in which the reference image is used as an intensity mask to enhance 3D image quality.

### BRIEF DESCRIPTION OF THE DRAWINGS

The following figures illustrate various aspects of the disclosure.

FIG. 1 is a schematic diagram illustrating the elements of a compressed ultrafast photography (CUP) system according to one aspect.

FIG. 2A is a schematic diagram illustrating the imaging of a stripe pattern using a CUP system according to one aspect.

FIG. 2B is an image of a reconstructed datacube of the striped pattern and a representative frame from the reconstructed datacube obtained using the CUP system illustrated in FIG. 2A.

FIG. 2C is a reference image obtained using a CUP system according to one aspect without introducing temporal dispersion.

FIG. 2D is a projected vertical stripe image obtained using a CUP system according to one aspect and calculated by summing over x, y, and t datacube voxels along a temporal axis.

FIG. 2E is a projected horizontal stripe image obtained using a CUP system according to one aspect and calculated by summing over x, y, and t datacube voxels along a temporal axis.

FIG. 2F is a graph comparing the average light fluence distributions along the x axis from FIG. 2C (Reference), along the x axis from FIG. 2D (CUP (x axis)), and along the y axis from FIG. 2E (CUP (y axis)).

FIG. 2G is a graph summarizing the spatial frequency responses of a CUP system according to one aspect for five different orientations of a stripe pattern.

FIG. 3A is a series of images of laser pulse reflection obtained using obtained using a CUP system according to one aspect.

FIG. 3B is a series of images of laser pulse refraction obtained using a CUP system according to one aspect.

FIG. 3C is a series of images of two laser pulses propagating in air and in resin obtained using a CUP system according to one aspect.

FIG. 3D is a graph comparing the change in position with time of a laser pulse in air and in resin measured from the images of FIG. 3C.

FIG. 4A is a photographic image of a stripe pattern with a constant period of 12 mm.

FIG. 4B is a series of images of an optical wavefront sweeping across the stripe pattern depicted in FIG. 4A that was obtained using a CUP system according to one aspect.

FIG. 4C is a schematic diagram illustrating the intersection of optical wavefronts with the pattern depicted in FIG. 4A.

FIG. 5A is a schematic diagram illustrating the elements of a multicolor compressed-sensing ultrafast photography (Multicolor-CUP) system according to one aspect.

FIG. 5B is a series of images of a pulsed-laser-pumped fluorescence emission process obtained using the multicolor compressed-sensing ultrafast photography (Multicolor-CUP) system illustrated in FIG. 5A.

FIG. 5C is a graph summarizing the time-lapse pump laser and fluorescence emission intensities within the dashed box shown in FIG. 5B.

FIG. 6A is a graph of an event function describing the pulsed laser fluorescence excitation from a simulated temporal response of a pulsed-laser-pumped fluorescence emission.

FIG. 6B is a graph of an event function describing the fluorescence emission from a simulated temporal responses of a pulsed-laser-pumped fluorescence emission.

FIG. 6C is a graph of a measured temporal point-spread-function (PSF).

FIG. 6D is a graph illustrating the simulated temporal responses of the two event functions shown in FIG. 6A and FIG. 6B after being convolved with the temporal PSF shown in FIG. 6C.

FIG. 7 is a schematic diagram illustrating a CUP image formation model according to one aspect.

FIG. 8 is an image of a temporally undispersed CCD image of a mask used to encode the uniformly illuminated field with a pseudo-random binary pattern according to the CUP imaging method according to one aspect.

FIG. 9 is a schematic diagram illustrating a time of flight-compressed ultrafast photography (ToF-CUP) 3D imaging system according to one aspect.

FIG. 10A is a schematic diagram of a target body positioned beneath a camera lens of a ToF-CUP system.

FIG. 10B is a graph of the reconstructed x, y, t_{ToF} datacube representing the backscattered laser pulse intensity from the fins with different depths of the target body illustrated in FIG. 10A.

FIG. 10C is a series of representative x-y frames obtained by a ToF-CUP system at t_{ToF}=120, 200, and 280 ps.

FIG. 11A is a depth-encoded ToF-CUP image of the stationary letters “W” and “U” with a depth separation of 40 mm.

FIG. 11B is a depth-encoded ToF-CUP image of a wooden mannequin.

FIG. 11C is a depth-encoded ToF-CUP image of a human hand.

FIG. 12A is a graph summarizing the cross-correlation coefficients between an image decrypted using the correct decryption key and images decrypted using 50 brute force attacks with incorrect random binary masks.

FIG. 12B is a graph illustrating a 3D datacube of the letters “W” and “U” (see FIG. 11A) decrypted using the correct decryption key.

FIG. 12C is a graph illustrating a 3D datacube of the letters “W” and “U” (see FIG. 11A) decrypted using an invalid correct decryption key from one of the brute force attacks presented in FIG. 12A.

FIG. 12D is a graph summarizing the cross-correlation coefficients between a reconstructed image decrypted using a correct decryption key and a series of images reconstructed using a subset of the correct decryption key with a different horizontal shifts to the left (negative pixel shift values) and to the right (positive pixel shifts).

FIG. 12E is a graph illustrating a 3D datacube of the letters “W” and “U” (see FIG. 11A) decrypted using the correct decryption key shifted horizontally by a single encoded pixel.

FIG. 13A is a schematic illustration of a target body that includes two rotating balls.

FIG. 13B is a series of representative depth-encoded 3D images obtained at different time points in the motion of the two balls showing the relative depth positions of the two balls.

FIG. 14A is a series of representative depth-encoded 3D images of a live comet goldfish swimming in a tank obtained at different time points in the motion of the goldfish.

FIG. 14B is graph summarizing changes in 3D position of a goldfish swimming in a tank obtained by the analysis of 3D images obtained using the ToF-CUP system according to one aspect.

FIG. 15A is a schematic diagram illustrating a moving target in a scattering medium.

FIG. 15B is a series of images of a moving object in a scattering medium obtained using a ToF CUP 3D imaging system according to one aspect.

FIG. 15C is a graph summarizing the normalized intensity profiles for a cross section of a target airplane wing at different scattering conditions.

FIG. 15D is a series of images of a moving object in a scattering medium obtained using a ToF CUP 3D imaging system according to one aspect.

FIG. 15E is a series of images of a moving object in a scattering medium obtained using a ToF CUP 3D imaging system according to one aspect.

While multiple embodiments are disclosed, still other embodiments of the present disclosure will become apparent to those skilled in the art from the following detailed description, which shows and describes illustrative embodiments of the disclosure. As will be realized, the invention is capable of modifications in various aspects, all without departing from the spirit and scope of the present disclosure. Accordingly, the drawings and detailed description are to be regarded as illustrative in nature and not restrictive.

### DETAILED DESCRIPTION

Provided herein are systems and methods for compressed-sensing ultrafast photography (CUP) for capturing images at up to 100 billion (10¹¹) frames per second. CUP overcomes the shortcomings of previous existing ultrafast imaging techniques by measuring two spatial coordinates (x, y) as well as time (t) with a single camera snapshot, thereby allowing observation of transient events occurring on a time scale down to tens of picoseconds. In an aspect, CUP may be used to visualize at least four fundamental physical phenomena using single laser pulses: laser pulse reflection, laser pulse refraction, photon racing in two media, and faster-than-light travel of non-information. Moreover, CUP's functionality may be expanded in reproducing colors of different wavelengths λ, thereby enabling single-shot four-dimensional (4D) (x, y, λ, t) measurements of a pulsed-laser-pumped fluorescence emission process with unprecedented temporal resolution. In addition, another aspect of the CUP method, time of flight CUP (ToF-CUP), may obtain the time-of-flight of pulsed light scattered by an object in order to reconstruct a volumetric image of the object from a single snapshot.

### Compressed-Sensing Ultrafast Photography System

a. Configuration

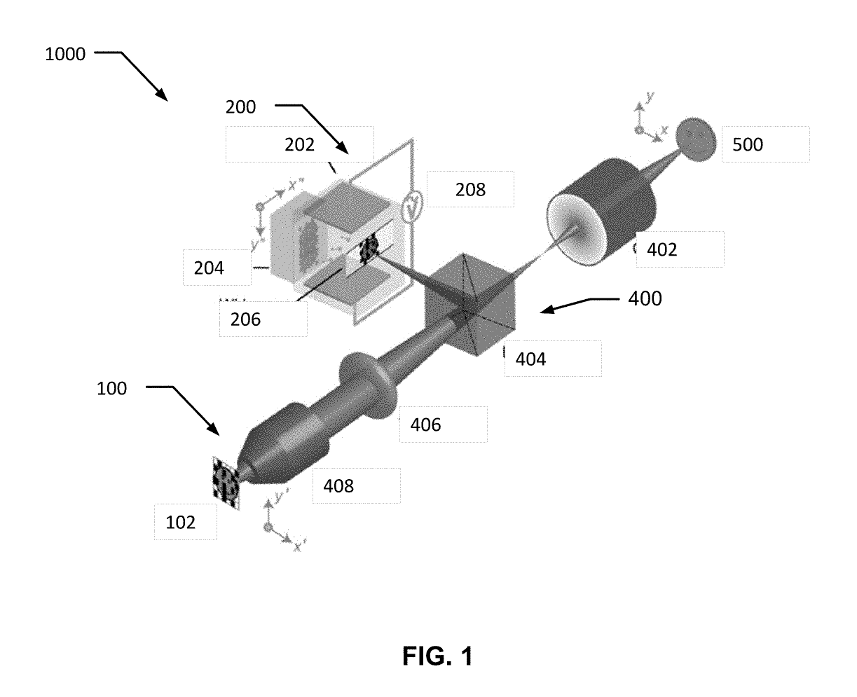

Provided herein is a compressed-sensing ultrafast photography system to obtain a series of recorded images of an object. FIG. 1 is a schematic diagram of a CUP system 1000 in one aspect. Referring to FIG. 1, the CUP system 1000 may include a spatial encoding module 100 and a temporal encoding module 200 operatively coupled to the spatial encoding module 100. The system 1000 may further include a spectral separation module 300 (not illustrated) operatively coupled to the spatial encoding module 100 and the temporal encoding module 200.

In an aspect, the spatial encoding module 100 receives a first series of object images and produces a second series of spatially encoded images. Each of the spatially encoded images of the second series includes an object image of the first series superimposed with a pseudo-random binary spatial pattern. The temporal encoding module 200 may receive an entire field of view of each spatially encoded image of the second series, deflect each spatially encoded image of the second series by a temporal deflection distance proportional to the time-of-arrival of each portion of each spatially encoded image of the second series. The temporal encoding module 200 also records each deflected spatially encoded image as a third series of spatially and temporally encoded images. Each spatially and temporally encoded image of the third series may include an object image superimposed with a pseudo-random binary spatial pattern and deflected by the temporal deflection distance.

In an aspect, the spectral separation module 300 deflects each spatially encoded image of the second series by a spectral deflection distance. In one aspect, the spectral deflection distance of the spectral encoding module 300 may be oriented perpendicular to the temporal deflection distance of the temporal encoding module 200. In an aspect, the spectral separation module 300 may receive the second series of spatially encoded images from the spatial encoding module. In another aspect, the spectral separation module 300 deflects a first spectral portion of each spatially encoded image including a first wavelength and a second spectral portion of each spatially encoded image including a second wavelength by a first and second spectral deflection distance proportional to the first and second wavelengths, respectively. In yet another aspect, the spectral separation module may produce a fourth series of spatially/spectrally encoded images, each spatially/spectrally encoded image comprising an object image superimposed with a pseudo-random binary spatial pattern and with the first and second spectral portions deflected by spectral deflection distances. In another aspect, the spectral separation module 300 may deflect more than 2 spectral portions corresponding to more than 2 different wavelengths. In various other aspects, the spectral separation module 300 may deflect up to 3 spectral portions corresponding to 3 different wavelengths, up to 4 spectral portions corresponding to 4 different wavelengths, up to 5 spectral portions corresponding to 5 different wavelengths, up to 6 spectral portions corresponding to 6 different wavelengths, up to 7 spectral portions corresponding to 7 different wavelengths, up to 8 spectral portions corresponding to 8 different wavelengths, up to 9 spectral portions corresponding to 9 different wavelengths, and up to 10 spectral portions corresponding to 10 different wavelengths.

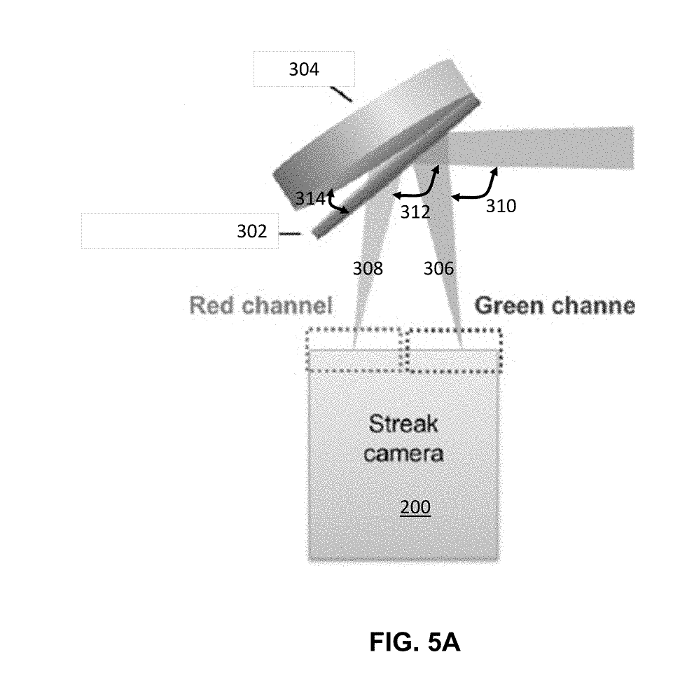

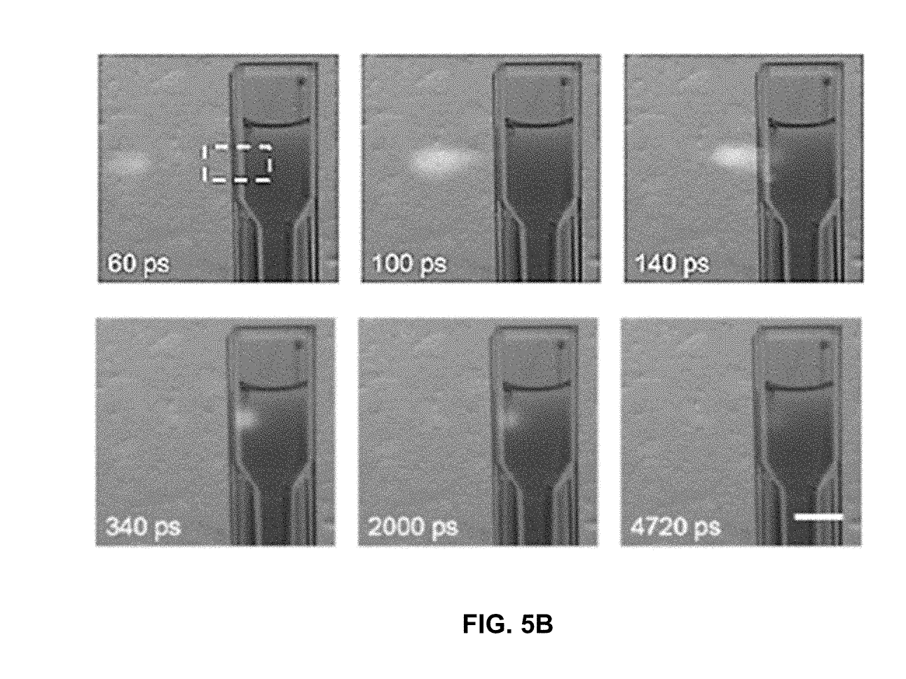

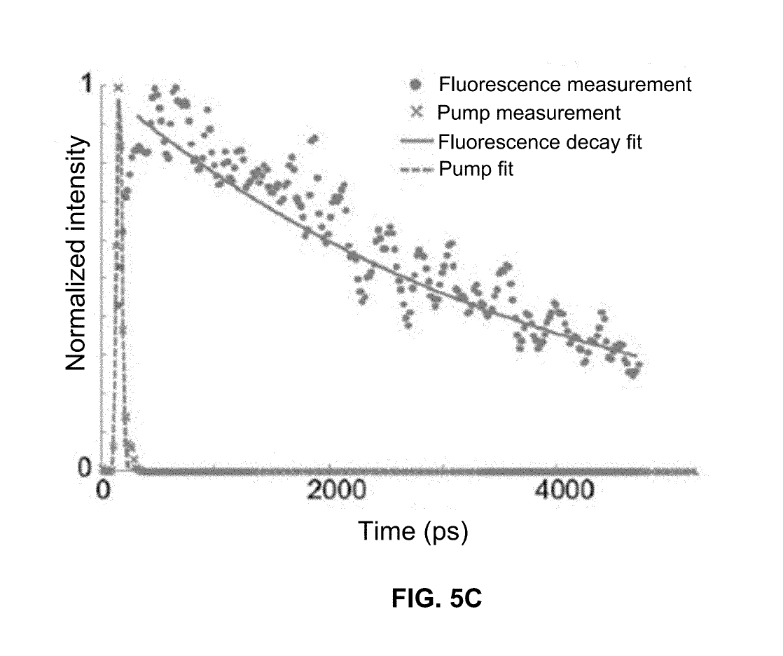

FIG. 5A is a schematic diagram of a spectral separation module 300 in one aspect. Referring to FIG. 5A, the spectral separation module 300 may include a dichroic filter 302 mounted on a mirror 304 at a tilt angle 314. In this aspect, the first spectral portion 306 of each spatially encoded image including the first wavelength reflects off of the dichroic filter 302 at a first angle 310 and the second spectral portion 308 of each spatially encoded image including the second wavelength passes through the dichroic filter 302 and reflects off of the mirror at a second angle 312 comprising the combined first angle 310 and tilt angle 314.

Referring again to FIG. 1, the spatial encoding module 100 may include a digital micromirror device (DMD) 102. The DMD 102 may include an array of micromirrors, where each micromirror may be configured to reflect or absorb a portion of the object image according to the pseudo-random binary pattern.

In various aspects, the temporal encoding module 200 enables temporal shearing of the spatially encoded images and spatiotemporal integration to produce the spatially and temporally encoded images of the third series of images to be analyzed according to the CUP image reconstruction methods described herein below. In various aspects, the temporal encoding module 200 includes any camera capable of performing the temporal shearing and spatiotemporal integration used to form a single spatially and temporally encoded image to be reconstructed according to the CUP reconstruction method described herein. In one aspect, the camera's exposure time spans the entire data acquisition process. During the exposure, images recorded from the previous time points are shifted in one spatial dimension and mixed with images recorded at following time points. All these temporally-sheared images are recorded in a single snapshot as the camera output. Non-limiting examples of camera types suitable for use as a temporal encoding module 200 includes a streak cameras, time-delay-and-integration (TDI) cameras, frame transfer CCD cameras including various types of sCMOS, ICCD, and EMCCD cameras that employ frame transfer CCD sensors.

Referring again to FIG. 1, the temporal encoding module 200 may include a streak camera 202, a 2D detector array 204, and combinations thereof in one aspect. The 2D detector array 204 may include, but is not limited to a CCD, CMOS, or any other detector array capable of capturing the encoded 3D scene. In an aspect, the entrance slit 206 of the streak camera 202 may be fully open. The temporal deflection distance may be proportional to the time-of-arrival and a sweep voltage 208 triggered within the streak camera 202. In one aspect, a CCD may be coupled to a streak camera 202 to form the temporal encoding module 200, such that the streak camera 202 performs a shearing operation in the temporal domain and the encoded 3D scene is measured by the CCD.

As used herein, the term “streak camera” refers to an ultrafast photo-detection system that transforms the temporal profile of a light signal into a spatial profile by shearing photoelectrons perpendicular to their direction of travel with a time-varying voltage. When used in conjunction with a narrow entrance slit, a typical streak camera is a one-dimensional (1D) imaging device. The narrow entrance slit, which ranges from about 10-50 μm in width, limits the imaging field of view (FOV) to a line. To achieve two-dimensional (2D) imaging with the narrow slit, additional mechanical or optical scanning may be incorporated along the other spatial axis. Although this paradigm is capable of providing a frame rate fast enough to catch photons in motion, the event itself must be repetitive, following exactly the same spatial-temporal pattern while the entrance slit of a streak camera scans across the entire FOV. In cases where the physical observations are either difficult or impossible to repeat, such as optical rogue waves, a nuclear explosion, or gravitational collapse in a supernova, this 2D streak imaging method is inapplicable.

Referring again to FIG. 1, 2D dynamic imaging is enabled using the streak camera 202 without employing any mechanical or optical scanning mechanism with a single exposure by fully opening the entrance slit 206 to receive a 2D image. In various aspects, the exposure time of the streak camera 202 outfitted with a fully-opened entrance slit 206 spans the time course of entire events, thereby obviating the need to observe multiple events as described previously in connection with the streak camera 202 with narrow entrance slit 206. In various aspect, the spatial encoding of the images performed by the spatial encoding module 100 enables the streak camera 202 to receive 2D images with minimal loss of spatial information.

Referring again to FIG. 1, the system 1000 may further include an optical module 400 to direct the first series of object images to the spatial encoding module 100 and to direct the second series of spatially encoded images to the temporal encoding module 200. The optical module 400 may include, but is not limited to a camera lens 402, a beam splitter 404, a tube lens 406, an objective 408, and combinations thereof. In an aspect, the optical module 400 includes the camera lens 402 operatively coupled to the beam splitter 404, the tube lens 406 coupled to the beam splitter 404, and an objective 408 operatively coupled to the tube lens 406. In this aspect, the camera lens 402 receives the first series of object images, the objective 408 is operatively coupled to the spatial encoding module 100 to deliver the first series of object images, and the beam splitter 404 is operatively coupled to the temporal encoding module 200 to deliver the second series of spatially encoded images via the objective 408 and tube lens 406.

In an aspect, the system 1000 may further include a microscope not illustrated) operatively coupled to the spatial encoding module 102. The first series of object images may include images of microscopic objects obtained by the microscope. In another aspect, the system 1000 may further include a telescope (not illustrated) operatively coupled to the spatial encoding module 100. In this other aspect, the first series of object images comprise images of distant objects obtained by the telescope.

Referring back to FIG. 1, the object 500 may first be imaged by a camera lens 402. In an aspect, the camera lens 402 may have a focal length (F.L.) of about 75 mm. The intermediate image may then be passed to a DMD 102 by a 4-f imaging system including a tube lens 406 (F.L.=about 150 mm) and a microscope objective 408 (F.L.=about 45 mm, NA=about 0.16). To encode the input image, a pseudo-random binary pattern may be generated and displayed on the DMD 102, with a single pixel size of about 21.6 μm×21.6 μm (3×3 binning). Since the DMD's resolution pixel size (7.2 μm×7.2 μm) may be much larger than the light wavelength, the diffraction angle may be small (˜4°). With a collecting objective 408 of an N.A.=0.16, the throughput loss caused by DMD's diffraction may be negligible.

The light reflected from the DMD 102 may be collected by the same microscope objective 408 and tube lens 406, reflected by a beam splitter 404, and imaged onto the entrance slit 206 of a streak camera 202. To allow 2D imaging, this entrance slit 206 may be opened to its maximal width (about 5 mm). Inside the streak camera 202, a sweeping voltage 208 may be applied along the y″ axis, deflecting the encoded images towards different y″ locations according to their times of arrival. The final temporally dispersed image may be captured by a CCD 204 within a single exposure. In an aspect, the CCD 204 may have 512×672 pixels; 12.9×12.9 μm² pixel size; and 2×2 binning

b. Effective Field-of-View Measurement

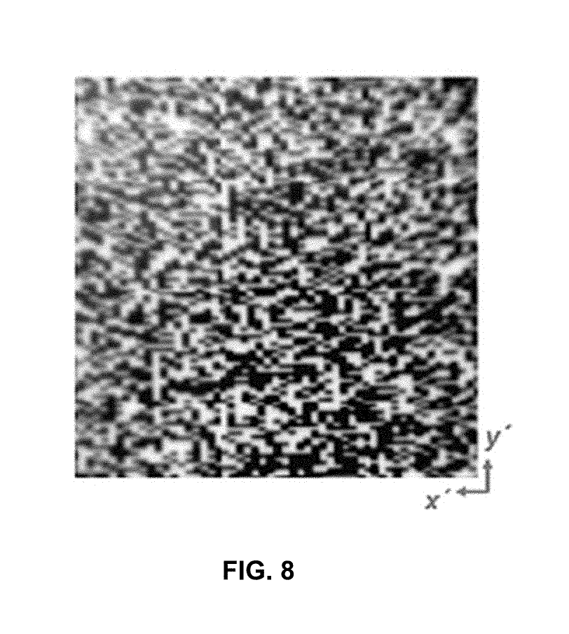

In CUP, a streak camera temporally disperses the light. The streak camera's entrance slit may be fully opened to a 17 mm×5 mm rectangle (horizontal×vertical axes). Without temporal dispersion, the image of this entrance slit on the CCD may have an approximate size of 510×150 pixels. However, because of a small angle between each individual micro-mirror's on-state normal and the DMD's surface normal, the DMD as a whole may need to be tilted horizontally so that the incident light can be exactly retroreflected. With an NA of 0.16, the collecting objective's depth of focus thereby may limit the horizontal encoding field of view (FOV) to approximately 150 pixels at the CCD. FIG. 8 shows a temporally undispersed CCD image of the DMD mask, which encodes the uniformly illuminated field with a pseudo-random binary pattern. The effective encoded FOV is approximately 150×150 pixels. Note that with temporal dispersion, the image of this entrance slit on the CCD may be stretched along the Y^{″} axis to approximately 150×500 pixels.

c. Calibration

To calibrate for operator matrix C, defined herein below, a uniform scene may be used as the input image and a zero sweeping voltage may be applied in the streak camera. The coded pattern on the DMD may therefore be directly imaged onto the CCD without introducing temporal dispersion. A background image may also be captured with all DMD pixels turned on. The illumination intensity non-uniformity may be corrected for by dividing the coded pattern image by the background image pixel by pixel, yielding operator matrix C. Note that because CUP's image reconstruction may be sensitive to mask misalignment, a DMD may be used for better stability rather than premade masks that would require mechanical swapping between system alignment and calibration or data acquisition.

d. Time of Flight CUP 3D Imaging System

In various aspects, the CUP imaging system 1000 may be modified by the addition of an illumination source conduct time of flight CUP (ToF-CUP) 3D imaging. In these various aspects, the CUP system is synchronized with short-pulsed laser illumination to enable dynamic three-dimensional (3D) imaging. By leveraging the time-of-flight (ToF) information of pulsed light backscattered by the object, ToF-CUP can reconstruct a volumetric image from a single camera snapshot. In addition, the approach unites the encryption of depth data with the compressed acquisition of 3D data in a single snapshot measurement, thereby allowing efficient and secure data storage and transmission.

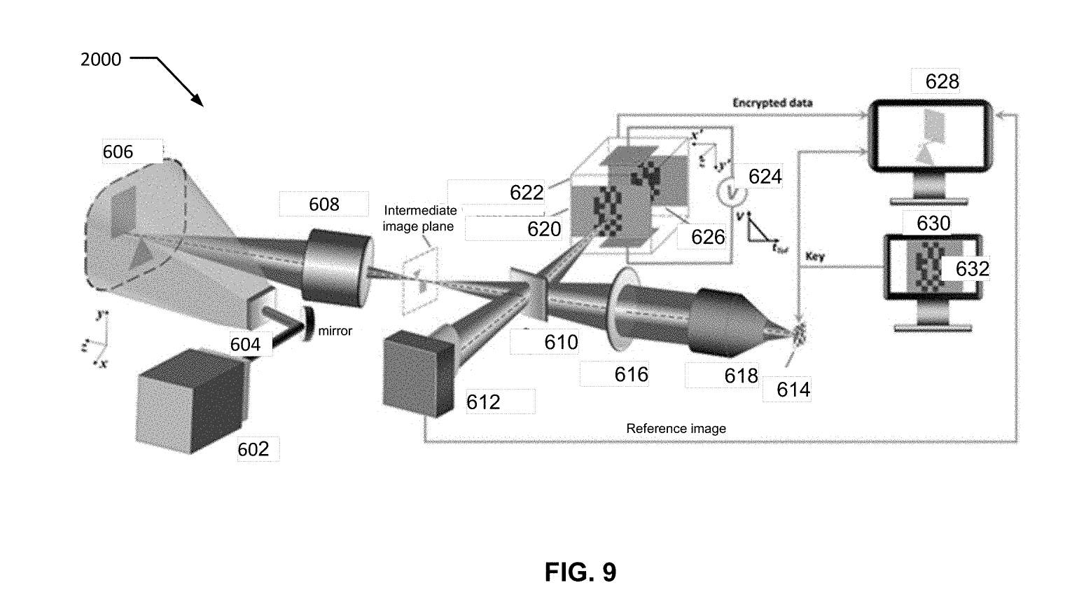

FIG. 9 is a schematic diagram of a ToF-CUP 3D imaging system 2000 in one aspect. A solid-state pulsed laser (532 nm wavelength, 7 ps pulse duration) is used as the light source 602. The laser beam passes through an engineered diffuser 604 and illuminates a 3D object 606. The object 606 is first imaged by a camera zoom lens 608 (focal length 18-55 mm). Following the intermediate image plane, a beam splitter 610 reflects half of the light to an external CCD camera 612, hereinafter called the reference camera, which records a reference 2D image of the 3D object 606. The other half of the light is transmitted through the beam splitter 610 and passed to a digital micromirror device (DMD) 614 by a 4-f imaging system consisting of a tube lens 616 and a microscope objective 618 (focal length 45 mm, numerical aperture 0.16). The total demagnification of the imaging system 2000 from the object 606 to the DMD 614 is about 46-fold.

To encrypt the input image, a pseudo-random binary pattern 632 is generated by the host 630 as the key and displayed on the DMD 614. Each encoded pixel in the binary pattern 632 contains 3×3 DMD pixels (21.6 nm×21.6 nm). The encrypted image is retro-reflected through the same 4-f system, reflected by the beam splitter 610, and imaged onto the fully opened entrance slit 620 (˜5 mm wide) of a streak camera 622. Deflected by a time-varying sweeping voltage 624, V, the light signal lands at various spatial locations on the y′ axis according to its ToF. This temporally sheared image is recorded by an internal CCD sensor 624 in a single snapshot. This CCD sensor 626 has 672×512 binned pixels (2×2 binning), and each encoded pixel is imaged by 3 ×3 binned CCD pixels. Finally, the encrypted data is transmitted to the user 628 who decrypts the image with the key provided by the host 630.

The external CCD camera 612 is synchronized with the streak camera 622 for each snapshot. An USAF resolution target is used to co-register images acquired by these two devices. Used as an intensity mask, the reference image is overlaid with the reconstructed 3D image to enhance the image quality. For each snapshot, the reconstructed 3D datacube contains Nₓ×N_{y}×N_{z}=150×150×350 voxels along the x, y, and z axes, respectively. In the x-y plane, this size gives a maximum imaging field-of-view (FOV) of Lₓ×L_{y}=150 mm×150 mm. Given the collocated illumination and detection, the depth, z, can be calculated by

$$z = {n}_{z} \frac{c d}{2 v} ( 1 \leq {n}_{z} \leq {N}_{z} ) , \qquad ( 5 )$$

where n_{z} is the pixel index along the z axis, d is the CCD's binned pixel size along the y′ axis, and v is the shearing velocity of the streak camera 622. In our experiments, N_{z}=350, d=12.9 μm, and v is set to 0.66 mm/ns. Therefore, the maximum depth range is L_{z}=1050 mm.

### CUP Method

Presented herein is an ultrafast 2D imaging technique, compressed-sensing ultrafast photography (CUP), which can capture non-repetitive events at up to 100 billion frames per second. CUP takes advantage of the compressibility of an event datacube and realizes an acquisition of petahertz data flux (105 frame pixels×1011 frames per second) using a CCD with only 0.3 megapixels. CUP has been demonstrated by imaging transient events involving fundamental physical phenomena such as light reflection, refraction, laser pulses racing in different media, and FTL travel of non-information. Furthermore, by utilizing a custom-built spectral separation unit, multicolor CUP may be accomplished, expanding its functionality into the realm of 4D x, y, λ, t ultrafast imaging.

In an aspect, the method may include obtaining a series of final recorded images of an object using a compressed-sensing ultrafast photography system at a rate of up to one billion frames per second. The method may include collecting a first series of object images, superimposing a pseudo-random binary spatial pattern onto each object image of the first series to produce a second series of spatially encoded images, deflecting each spatially encoded image of the second series by a temporal deflection distance proportional to a time-of-arrival of each spatially encoded image, recording each deflected spatially encoded image as a third series of spatially/temporally encoded images, and reconstructing a fourth series of final object images by processing each spatially/temporally encoded image of the third series according to an image reconstruction algorithm.

The CUP system's frame rate and temporal resolution may be determined by the shearing velocity of the streak camera: a faster shearing velocity results in a higher frame rate and temporal resolution. Unless the illumination is intensified, however, the shortened observation time window may reduce the signal-to-noise ratio, which may reduce image reconstruction quality. The shearing velocity thus may be balanced to accommodate a specific imaging application at a given illumination intensity.

In an aspect, the size of the reconstructed event datacube, Nₓ×N_{y}×Nₜ (Nₓ,N_{y}, and Nₜ: the numbers of voxels along x, y, and t), may be influenced by the acceptance NA of the collecting objective, photon shot noise, and sensitivity of the photocathode tube as well as by the number of binned CCD pixels (N_{R}×N_{C}; N_{R}, the number of rows; N_{C}, the number of columns). Provided that the image formation closely follows the ideal forward model, the number of binned CCD pixels may become an additional influencing factor on the size of the reconstructed event datacube. Along the horizontal direction, the number of reconstructed voxels may be less than the number of detector columns, i.e., Nₓ≤N_{C}. In multicolor CUP, this becomes Nₓ≤N_{C}/N_{L}, where N_{L} is the number of spectral channels (i.e., wavelengths). Along the vertical direction, to avoid field clipping, the sampling obeys N_{y}+Nₜ−1≤N_{R} because the spatial information and temporal information overlap and occupy the same axis.

Secure communication using CUP may be possible because the operator O is built upon a pseudo-randomly generated code matrix sheared at a preset velocity. The encrypted scene therefore may be decoded by only recipients who are granted access to the decryption key. Using a DMD (instead of a premade mask) as the field encoding unit in CUP facilitates pseudo-random key generation and potentially allows the encoding pattern to be varied for each exposure transmission, thereby minimizing the impact of theft with a single key decryption on the overall information security. Furthermore, compared with other compressed-sensing-based secure communication methods for either a 1D signal or a 2D image, CUP operates on a 3D dataset, allowing transient events to be captured and communicated at faster speed.

CUP may be potentially coupled to a variety of imaging modalities, such as microscopes and telescopes, allowing imaging of transient events at scales from cellular organelles to galaxies. For example, in conventional fluorescence lifetime imaging microscopy (FLIM), point scanning or line scanning is typically employed to achieve 2D fluorescence lifetime mapping. However, since these scanning instruments cannot collect light from all elements of a dataset in parallel, there is a loss of throughput by a factor of Nₓ×N_{y} (point scanning) or N_{y} (line scanning) when measuring an image of Nₓ×N_{y} pixels. Additionally, scanning-based FLIM suffers from severe motion artifacts when imaging dynamic scenes, limiting its application to fixed or slowly varying samples. By integrating CUP with FLIM, parallel acquisition of a 2D fluorescence lifetime map may be accomplished within a single snapshot, thereby providing a simple solution to these long-standing problems in FLIM.

a. Image Formation and Reconstruction

In an aspect, CUP may operate in two steps: image formation and image reconstruction. In a non-limiting example, the image formation may be described by a forward model. During this step, the input image may be encoded with a pseudo-random binary pattern and then temporally dispersed along a spatial axis using a streak camera. Mathematically, this process is equivalent to successively applying a spatial encoding operator, C, and a temporal shearing operator, S, to the intensity distribution from the input dynamic scene, I(x, y, t):

Iₛ(x″, y″, t)=SCI(x, y, t), (1)

Where Iₛ(x″,y″,t) represents the resultant encoded, sheared scene. Next, Iₛ may be imaged by a CCD, a process that may be mathematically formulated as Eqn. 2:

E(m,n)=TIₛ(x″, y″, t). (2)

Here, T is a spatiotemporal integration operator (spatially integrating over each CCD pixel and temporally integrating over the exposure time). E(m,n) is the optical energy measured at pixel m, n on the CCD. Substituting Eqn. 1 into Eqn. 2 yields

E(x′, y′)=OS(x, y, t), (3)

where O represents a combined linear operator, i.e., O=TSC.

The image reconstruction is solving the inverse problem of Eq. 3. Given the operator O and spatiotemporal sparsity of the event, the input scene, I(x, y, t), can reasonably be estimated from measurement, E(m,n), by adopting a compressed-sensing algorithm, such as Two-Step Iterative Shrinkage/Thresholding (TwIST). The reconstructed frame rate, r, is determined by

$$r = \frac{v}{Δ {y}^{″}} . \qquad ( 4 )$$

Here, v is the temporal shearing velocity of the operator S, i.e., the shearing velocity of the streak camera, and Δy″ is the CCD's binned pixel size along the temporal shearing direction of the operator S.

b. Forward Model

CUP's image formation process may use a forward model. The intensity distribution of the dynamic scene, I(x, y, t), is first imaged onto an intermediate plane by an optical imaging system. Under the assumption of unit magnification and ideal optical imaging—i.e., the point-spread-function (PSF) approaches a delta function, the intensity distribution of the resultant intermediate image is identical to that of the original scene. To encode this image, a mask which contains pseudo-randomly distributed, squared, and binary-valued (i.e., either opaque or transparent) elements is placed at this intermediate image plane. The image immediately after this encoding mask has the following intensity distribution:

$${I}_{c} ( {x}^{′} , {y}^{′} , t ) = {\sum }_{i , j} I ( {x}^{′} , {y}^{′} , t ) {C}_{i , j} rect [ \frac{{x}^{′}}{{d}^{′}} - ( i + \frac{1}{2} ) , \frac{{y}^{′}}{{d}^{′}} - ( j + \frac{1}{2} ) ] . \qquad ( 5 )$$

Here, C is an element of the matrix representing the coded mask, i, j are matrix element indices, and d′ is the mask pixel size. For each dimension, the rectangular function is defined as

$$rect ( x ) = \{ \begin{matrix}1 , & if \vert x \vert \leq \frac{1}{2} \\ 0 , & else\end{matrix} .$$

In this section, a mask or camera pixel is equivalent to a binned DMD or CCD pixel defined in the experiment.

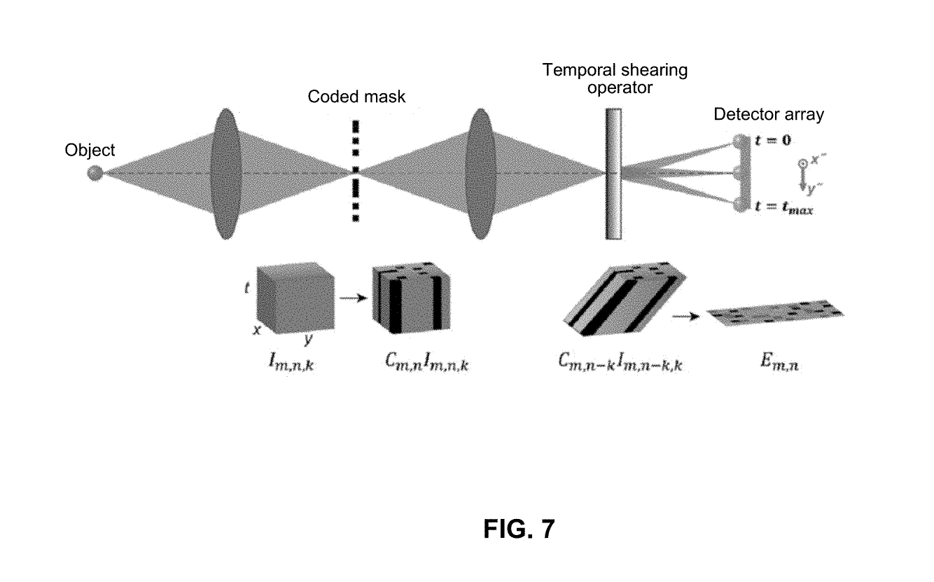

This encoded image is then passed to the entrance port of a streak camera. By applying a voltage ramp, the streak camera acts as a shearing operator along the vertical axis (axis in FIG. 7) on the input image. FIG. 7 is a CUP image formation model, where x, y, are spatial coordinates; t is time; m, n, k are matrix indices; I_{m,n,k} is input dynamic scene element; C_{m,n} is coded mask matrix element; C_{m,n-k}I_{m,n-k,k} is encoded and sheared scene element; E_{m,n} is image element energy measured by a 2D detector array; and tₘₐₓ is maximum recording time.

If ideal optics are assumed with unit magnification, the sheared image may be expressed as

Iₛ(x″, y″, t)=I_{c}(x″, y″−vt,t), (6)

where v is the shearing velocity of the streak camera.

Iₛ(x″, y″, t) is then spatially integrated over each camera pixel and temporally integrated over the exposure time. The optical energy, E(m,n), measured at pixel m, n, is

$$E ( m , n ) = \int dt \int {dx}^{″} \int {dy}^{″} {I}_{s} ( {x}^{″} , {y}^{″} , t ) rect [ \frac{{x}^{″}}{{d}^{″}} - ( m + \frac{1}{2} ) , \frac{{y}^{″}}{{d}^{″}} - ( n + \frac{1}{2} ) ] . \qquad ( 7 )$$

Here, d″ is the camera pixel size. Accordingly, the input scene, I(x, y, t), can be voxelized into I_{i,j,k} as follows:

$$I ( x , y , t ) \approx {\sum }_{i , j , k} {I}_{i , j , k} rect [ \frac{x}{{d}^{″}} - ( i + \frac{1}{2} ) , \frac{y}{{d}^{″}} - ( j + \frac{1}{2} ) , \frac{t}{{Δ}_{t}} - ( k + \frac{1}{2} ) ] , \qquad ( 8 )$$

where Δₜ=d″/v. If the mask elements are mapped 1:1 to the camera pixels (i.e., d′=d″) and perfectly registered, combining Eq. 5-8 yields

$$E ( m , n ) = \frac{{d}^{″3}}{v} {\sum }_{k = 0}^{n - 1} {C}_{m , n - k} {I}_{m , n - k , k} . \qquad ( 9 )$$

Here C_{m,n-k}I_{m,n-k,k} represents a coded, sheared scene, and the inverse problem of Eq. S5 can be solved using existing compressed-sensing algorithms.

It is worth noting that only those indices where n−k>0 should be included in Eqn. 9. Thus, to convert Eqn. 9 into a matrix equation, the matrices C and I need to be augmented with an array of zeros. For example, to estimate a dynamic scene with dimensions Nₓ×N_{y}×Nₜ, where the coded mask itself has dimensions Nₓ×N_{y}, the actual matrices I and C used in Eq. 9 will have dimensions Nₓ×(N_{y}+Nₜ₋₁)×Nₜ and Nₓ×(N_{y}+Nₜ₋₁), respectively, with zeros padded to the ends. After reconstruction, these extra voxels, containing nonzero values due to noise, are simply discarded.

c. CUP Image Reconstruction Algorithm

Given prior knowledge of the coded mask matrix, to estimate the original scene from the CUP measurement, the inverse problem of Eqn. 9 needs to be solved. This process can be formulated in a more general form as

arg min {1/2∥E−OI∥²+βΦ(I)}, (10)

where O is the linear operator, Φ(I) is the regularization function, and β is the regularization parameter. In CUP image reconstruction, an algorithm called Two-Step Iterative Shrinkage/Thresholding (TwIST) may be used, with Φ(I) in the form of total variation (TV):

$${Φ}_{TV} ( I ) = {\sum }_{k = 0}^{{N}_{t} - 1} {\sum }_{i = 1}^{{N}_{x} \times {N}_{y}} \sqrt{{( {Δ}_{i}^{h} {I}_{k} )}^{2} + {( {Δ}_{i}^{v} {I}_{k} )}^{2}} + {\sum }_{m = 1}^{{N}_{x}} {\sum }_{i = 1}^{{N}_{y} \times {N}_{t}} \sqrt{{( {Δ}_{i}^{h} {I}_{m} )}^{2} + {( {Δ}_{i}^{v} {I}_{m} )}^{2}} + {\sum }_{n = 1}^{{N}_{y}} {\sum }_{i = 1}^{{N}_{x} \times {N}_{t}} \sqrt{{( {Δ}_{i}^{h} {I}_{n} )}^{2} + {( {Δ}_{i}^{v} {I}_{n} )}^{2}} . \qquad ( 11 )$$

Here the discretized form of I is assumed to have dimensions Nₓ×N_{y}×Nₜ, and m, n, k are the three indices. Iₘ, Iₙ, Iₖ denote the 2D lattices along the dimensions m, n, k, respectively. Δᵢ^{h} and Δᵢ^{v} are horizontal and vertical first-order local difference operators on a 2D lattice. In TwIST, the minimization of the first term, ∥E−OI∥², occurs when the actual measurement E closely matches the estimated measurement OI, while the minimization of the second term, βΦ(I), encourages I to be piecewise constant (i.e., sparse in the gradient domain). The weighting of these two terms is empirically adjusted by the regularization parameter, β, to lead to the results that are most consistent with the physical reality. To reconstruct a datacube of size 150×150×350 (x, y, t), approximately ten minutes is required on a computer with Intel i5-2500 CPU (3.3 GHz) and 8 GB RAM. The reconstruction process may be further accelerated by using GPUs.

Traditionally, the TwIST algorithm is initialized with a pseudo-random matrix as the discretized form of and then converged to a solution by minimizing the objective function in Eqn. 10. Thus no spatiotemporal information about the event is typically employed in the basic TwIST algorithm. However, it is important to remember that the solution of TwIST might not converge to a global minimum, and hence might not provide a physically reasonable estimate of the event. Therefore, the TwIST algorithm may include a supervision step that models the initial estimate of the event. For example, if the spatial or temporal range within which an event occurs is known a priori, one can assign non-zero values to only the corresponding voxels in the initial estimate of the discretized form of I and start optimization thereafter. Compared with the basic TwIST algorithm, the supervised-TwIST approach can significantly reduce reconstruction artefacts and therefore provide a more reliable solution.

d. ToF-CUP Image Reconstruction Algorithm

In various aspect, the CUP system is provided with active illumination to enable ToF-CUP 3D imaging that uses the time of flight of photons backscattered from a 3D object to reconstruct a 3D image of an object. For collocated illumination and detection, the round-trip ToF signal carries information about the depth, z, relative to the point of light incidence on the object's surface, which can be recovered by

z=ct_{ToF}/2, (12)

where t_{ToF} is the ToF of received photons, and c is the speed of light. The factor of two in the denominator on the right side of Eq. 12 accounts for the round-trip flight of photons.

A collimated laser beam illuminates the 3D object having intensity reflectivity R(x, y, z). The backscattered light signal from this 3D object, I(x, y ,t_{ToF}), enters the ToF-CUP system 2000 described herein. The depth information of the 3D object is conveyed as the ToF of the backscattered light signal. Mathematically, this process can be described by

I(x, y, t_{ToF})=PR(x, y, z) (13)

where P is a linear operator for light illumination and backscattering. Considering that the scattering is a linear process, I(x, y , t_{ToF}) is linearly proportional to R(x, y, z). The ToF-CUP system then images this 3D object in three steps. First, the collected photons are spatially encrypted with a pseudo-random binary pattern, in which each pixel is set to either on or off. This pattern also acts as the decryption key to unlock and retrieve the image of the 3D object. Second, a streak camera temporally shears the ToF signal along the vertical direction. Third, the encrypted and sheared image is recorded on a CCD sensor in the streak camera via pixel-wise spatiotemporal integration. The optical energy measured at pixel (m, n) on the CCD, E(m, n), is related to the original 3D light intensity reflectivity, R(x, y, z), by

E(m, n)=TSCPR(x , y, z) (14)

Here, T, S, and C are linear operators that represent spatiotemporal integration, temporal shearing, and spatial encryption, respectively. Equation 14 shows that the encryption process is inherently embedded in the ToF-CUP method.

Image decryption can be computationally performed by users who are granted the decryption key. If the 3D object is spatiotemporally sparse, I(x, y, t_{ToF}) can be reasonably estimated by solving the inverse problem of Eq. (14) using compressed-sensing algorithms. In one aspect, a two-step iterative shrinkage/thresholding (TwIST) algorithm may be used, which minimizes a convex objective function given by

arg min [1/2∥E−TSCPR∥²+λΦ_{TV}(PR)]. (15)

where Φ_{TV} denotes the total-variation (TV) regularizer that encourages sparsity in the gradient domain during reconstruction.

The TwIST algorithm is initialized with a pseudo-random matrix of the discretized form of PR and then converged to a solution by minimizing the objective function in Eq. 15. The regularization parameter λ, which controls the weight of the TV regularizer, is adjusted empirically to provide the best for a given physical reality. Finally, R(x, y, z) can be recovered given the linear relation between the backscattered light signal and the intensity reflectivity of the object. Further, in continuous shooting mode, the evolution of the 3D images over the “slow time”, tₛ, R(x, y, z, tₛ), can be recovered by decrypting sequential snapshots. Here, the “slow time”, tₛ, relative to t_{ToF}, is defined as the time of capture of the imaged volume.

Besides security, the ToF-CUP method offers the advantage of more efficient information storage and transmission because data is compressed during acquisition. ToF-CUP method compresses a 3D datacube with Nₓ×N_{y}×N, voxels to a 2D encrypted image with <Nₓ×(N_{y}+N_{z}−1) pixels. The data compression ratio can therefore be calculated as

$${η}_{d} = \frac{{N}_{y} \times {N}_{z}}{( {N}_{y} + {N}_{z} - 1 )} .$$

With the current setup (N_{y}=150 and N_{z}=350), η_{d}=105. Therefore, ToF-CUP can potentially improve the data transmission rate by over two orders of magnitude. However, compared with optical bandwidth-limited images, the implementation of ToF-CUP degrades the spatial resolutions by factors of 1.8 and 2.2 along the x and y axes. In addition, the depth resolution is degraded by 3.3 along the z axis, compared to the streak camera's native resolution in resolving a ToF signal. Thus, regarding actual information content, the data compression ratio may be estimated by

$${η}_{i} = \frac{{η}_{d}}{1.8 \times 2.2 \times 3.3} .$$

For the current system, βᵢ=8.0.

### EXAMPLES

### Example 1

### 2D Ultrafast Imaging of the Impingement of a Laser Pulse Upon a Stripe Pattern and Characterization of the System's Spatial Frequency Responses

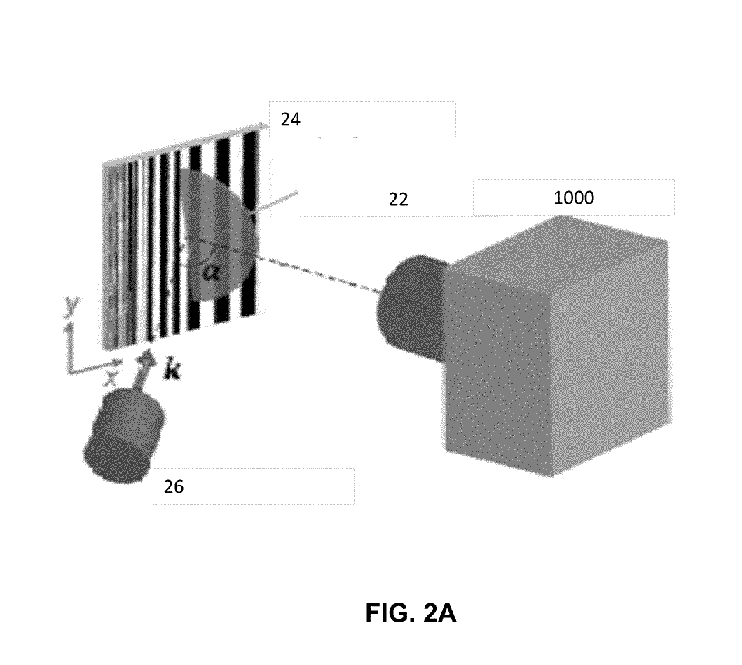

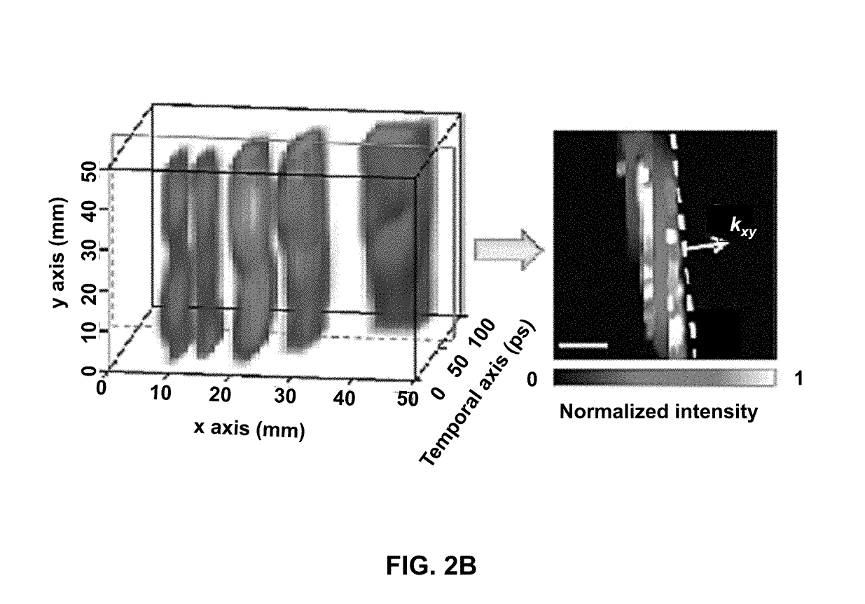

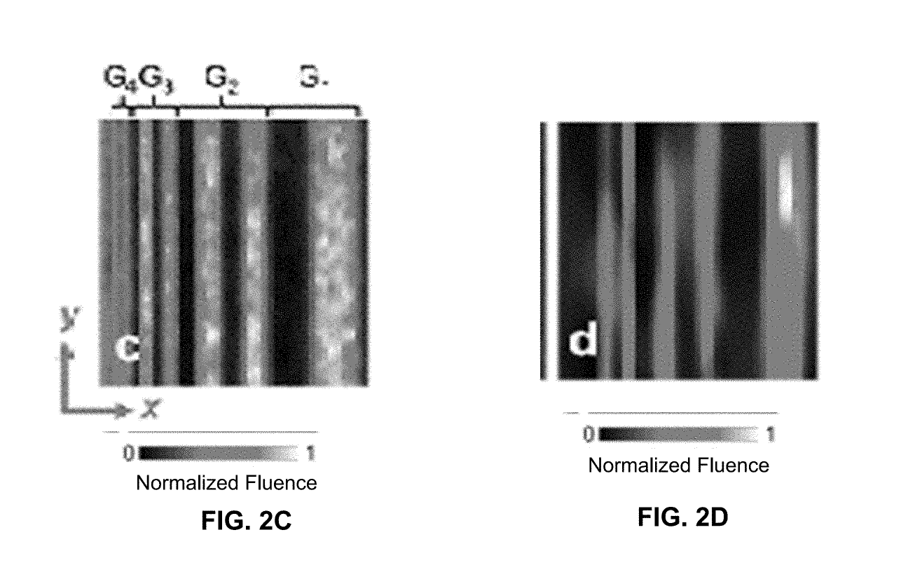

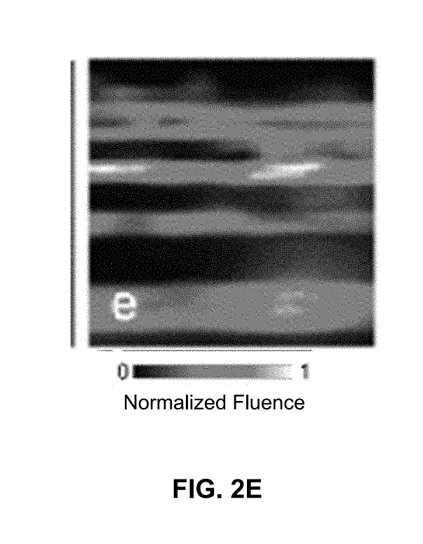

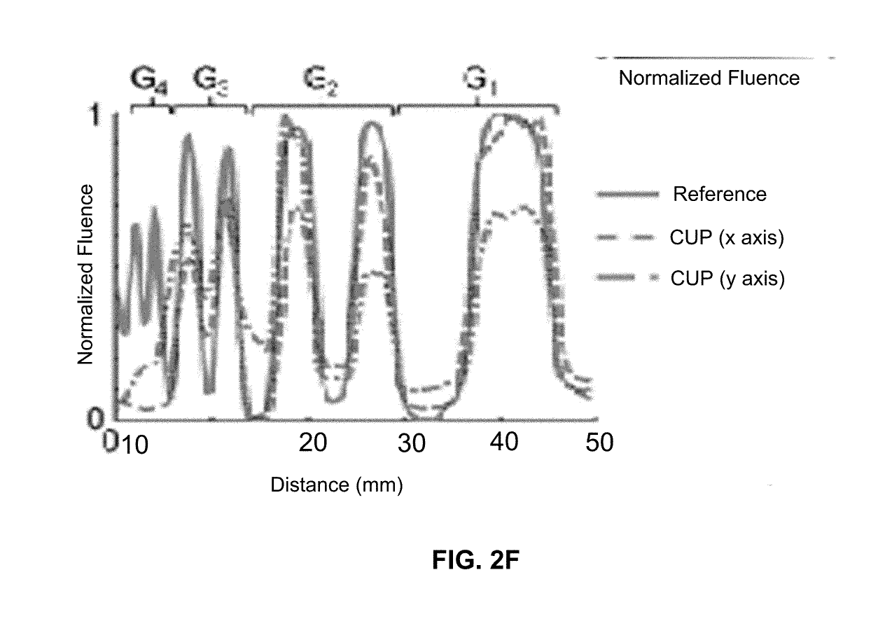

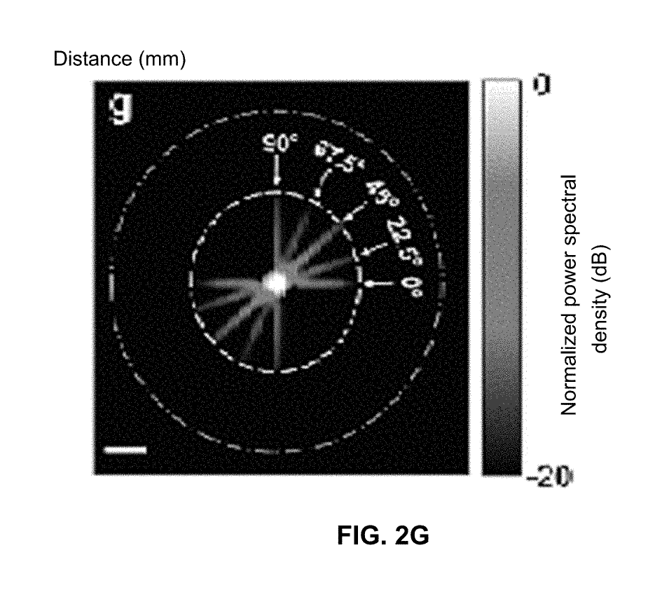

To characterize the system's spatial frequency responses, a dynamic scene was imaged. A laser pulse 22 impinging upon a stripe pattern 24 with varying periods is shown in FIG. 2A. The stripe periods frequency (in line pairs/mm) descends stepwise along the x axis from one edge to the other. A pulsed laser 26 delivered a collimated laser pulse (532 nm wavelength, 7 ps pulse duration, Attodyne APL-4000) to the stripe pattern 24 at an oblique angle of incidence α of about 30 degrees. The imaging system 1000 faced the pattern surface 24 and collected the scattered photons from the scene. The impingement of the light wavefront upon the pattern surface 24 was imaged by CUP at 100 billion frames per second with the streak camera's shearing velocity set to 1.32 mm/ns. The reconstructed 3D x, y, t image of the scene in intensity (W/m²) is shown in FIG. 2B, and the corresponding time-lapse 2D x, y images (50 mm×50 mm FOV; 150×150 pixels frame size) were created.

FIG. 2B also shows a representative temporal frame at t=60 ps. The dashed line indicates the light wavefront on the pattern surface, and the arrow denotes the in-plane light propagation direction (k_{xy}). Within a 10 ps frame exposure, the wavefront propagates about 3 mm in space. Including the thickness of the wavefront itself, which is about 2 mm, the wavefront image is approximately 5 mm thick along the wavefront propagation direction. The corresponding intersection with the x-y plane is 5 mm/sin α≈10 mm thick, which agrees with the actual measurement (about 10 mm).

To provide a reference, the scene was directly imaged in fluence (J/m²) without introducing temporal dispersion (FIG. 2C). Next, the stripe pattern was rotated in 22.5° steps to four additional angles (22.5°, 45°, 67.5°, and 90° with respect to the x axis) and repeated the light sweeping experiment. The x, y, t scenes were projected onto the x, y plane by summing over the voxels along the temporal axis. The resultant images at two representative angles (0° and 90°) are shown in FIGS. 2D and 2E, respectively. The average light fluence distributions were compared along the x axis from FIG. 2C and FIG. 2D as well as that along the y axis from FIG. 2E. The comparison in FIG. 2F indicates that the CUP system can recover spatial frequencies up to 0.3 line pairs/mm (groups G₁, G₂, and G₃) along both x and y axes; however, the stripes in group G₄—having a fundamental spatial frequency of 0.6 line pairs/mm—are beyond the CUP system's resolution. This bandwidth limitation was further analysed by computing the spatial frequency spectra of the average light fluence distributions for all five orientations (FIG. 2G). Each angular branch appears continuous rather than discrete because the object has multiple stripe groups of varied frequencies and each has a limited number of periods. As a result, the spectra from the individual groups are broadened and overlapped. The CUP's spatial frequency response band is delimited by the inner white dashed circle, whereas the band purely limited by the optical modulation transfer function of the system without temporal shearing—derived from the reference image (FIG. 2C)—is enclosed by the outer yellow dash-dotted circle. Thus, the CUP system achieved temporal resolution at the expense of some spatial resolution.

### Example 2

### 2D Ultrafast Imaging of Laser Pulse Reflection, Refraction, and Racing of Two Pulses in Different Media, and Characterization of the System's Temporal Resolution

To demonstrate CUP's 2D ultrafast imaging capability, three fundamental physical phenomena were imaged with single laser shots: laser pulse reflection, refraction, and racing of two pulses in different media (air and resin). It is important to mention that one-time events were truly recorded: only a single laser pulse was fired during image acquisition. In these experiments, to encompass the events within a preset time window (10 ns) on the streak camera, the pulsed laser (Attodyne APL-4000) was synchronized with the streak camera through a digital delay generator (Stanford Research Systems DG645). Moreover, to scatter light from the media to the CUP system, dry ice was evaporated into the light path in the air and added zinc oxide powder into the resin, respectively.

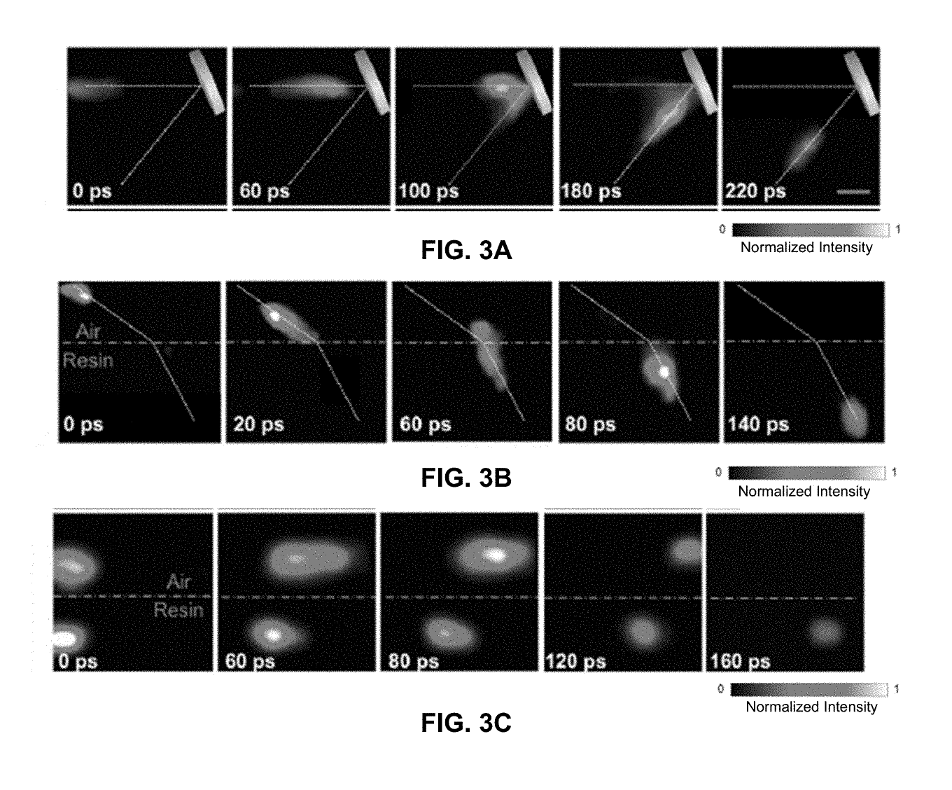

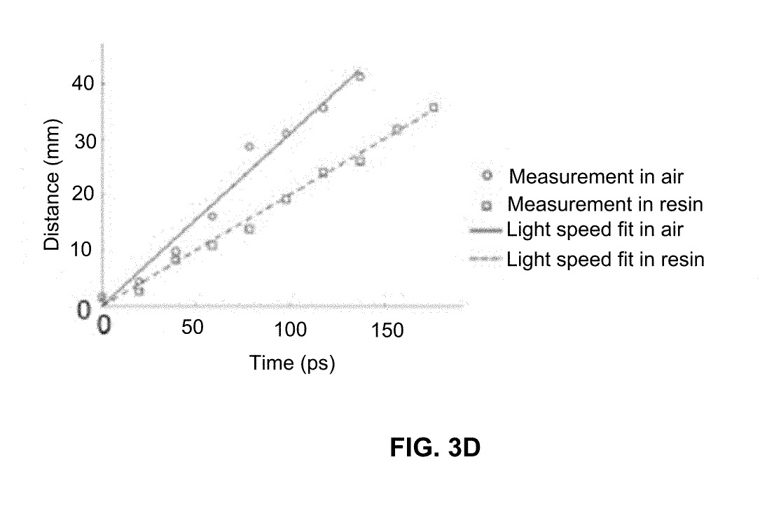

FIGS. 3A and 3B show representative time-lapse frames of a single laser pulse reflected from a mirror in the scattering air and refracted at an airresin interface, respectively. With a shearing velocity of 0.66 mm/ns in the streak camera, the reconstructed frame rate is 50 billion frames per second. Such a measurement allows the visualisation of a single laser pulse's compliance to the laws of light reflection and refraction, the underlying foundations of optical science. It is worth noting that the heterogeneities in the images are likely attributable to turbulence in the vapour and non-uniform scattering in the resin.

To validate CUP's ability to quantitatively measure the speed of light, photon racing was imaged in real time. The original laser pulse was split into two beams: one beam propagated in the air and the other in the resin. The representative time-lapse frames of this photon racing experiment are shown in FIG. 3C. As expected, due to the different refractive indices (1.0 in air and 1.5 in resin), photons ran faster in the air than in the resin. By tracing the centroid from the time-lapse laser pulse images (FIG. 3D), the CUP-recovered light speeds in the air and in the resin were (3.1±0.5)×10⁸ m/s and (2.0±0.2)×10⁸ m/s, respectively, consistent with the theoretical values (3.0×10⁸ m/s and 2.0×10⁸ m/s). Here the standard errors are mainly attributed to the resolution limits.

By monitoring the time-lapse signals along the laser propagation path in the air, CUP's temporal resolution was quantified. Because the 7 ps pulse duration is shorter than the frame exposure time (20 ps), the laser pulse was considered as an approximate impulse source in the time domain. The temporal point-spread-functions (PSF) were measured at different spatial locations along the light path imaged at 50 billion frames per second (20 ps frame exposure time), and their full widths at half maxima averaged 74 ps. Additionally, to study the dependence of CUP's temporal resolution on the frame rate, this experiment was repeated at 100 billion frames per second (10 ps frame exposure time) and re-measured the temporal PSFs. The mean temporal resolution was improved from 74 ps to 31 ps at the expense of signal-to-noise ratio. At a higher frame rate (i.e., higher shearing velocity in the streak camera), the light signals are spread over more pixels on the CCD camera, reducing the signal level per pixel and thereby causing more potential reconstruction artefacts.

### Example 3

### 2D Ultrafast Imaging of Faster-than-Light (FTL) Travel of Non-Information

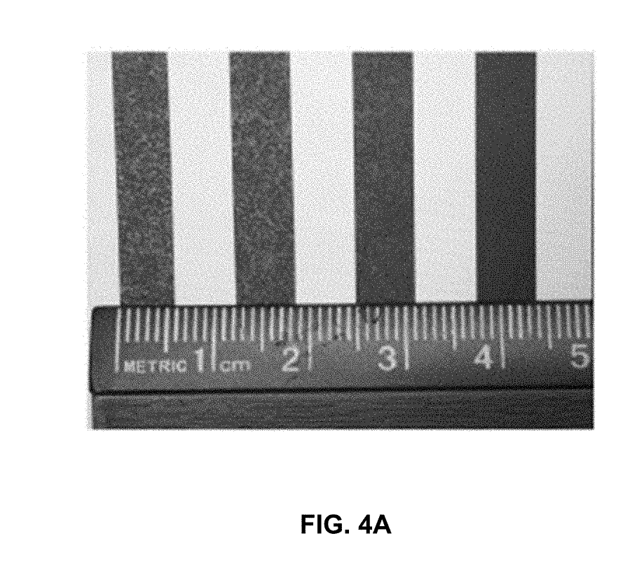

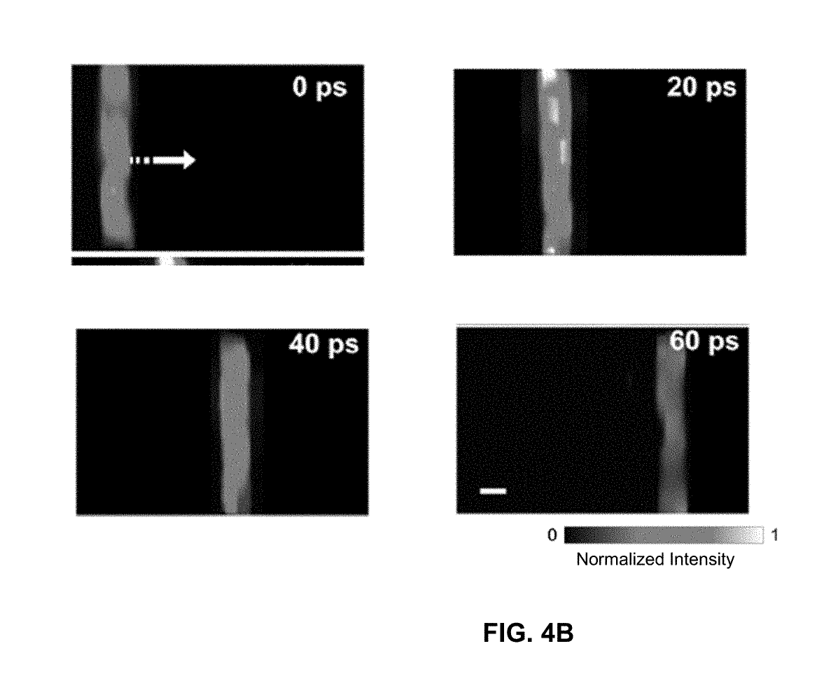

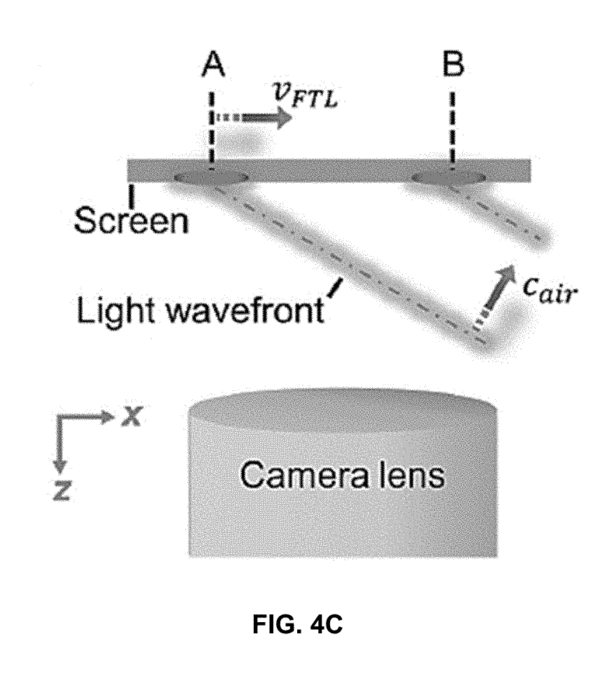

To explore CUP's potential application in modern physics, apparent faster-than-light phenomena were imaged in 2D movies. According to Einstein's theory of relativity, the propagation speed of matter cannot surpass the speed of light in vacuum because it would need infinite energy to do so. Nonetheless, if the motion itself does not transmit information, its speed can be faster than light. This phenomenon is referred to as faster-than-light propagation of non-information. To visualise this phenomenon with CUP, an experiment was designed using a setup similar to that shown in FIG. 2A. The pulsed laser illuminates the scene at an oblique angle of incidence of about 30 degrees, and CUP images the scene normally (0 degree angle). To facilitate the calculation of speed, a stripe pattern was imaged with a constant period of 12 mm (FIG. 4A).

The movement of a light wavefront intersecting with this stripe pattern is captured at 100 billion frames per second with the streak camera's shearing velocity set to 1.32 mm/ns. Representative temporal frames are provided in FIG. 4B. As shown in FIG. 4B, the white stripes shown in FIG. 4A are illuminated sequentially by the sweeping wavefront. The speed of this motion, calculated by dividing the stripe period by their lit-up time interval, is v_{FTL}=12 mm/20 ps=6×10⁸ m/s, two times of the speed of light in the air due to the oblique incidence of the laser beam. As shown in FIG. 4C, although the intersected wavefrontthe only feature visible to the CUP systemtravels from location A to B faster than the light wavefront, the actual information is carried by the wavefront itself, and thereby its transmission velocity is still limited by the speed of light in the air.

### Example 4

### Multicolor Compressed-Sensing Ultrafast Photography (Multicolor-CUP)

To extend CUP's functionality to reproducing colors, a spectral separation module was added in front of the streak camera. As shown in FIG. 5A, a dichroic filter 302 (562 nm cut-on wavelength) is mounted on a mirror 304 at a small tilt angle 314 (˜5°). The light reflected from this module is divided into two beams according to the wavelength: green light (wavelength<562 nm) is directly reflected from the dichroic filter 302, while red light (wavelength>562 nm) passes through the dichroic filter 302 and bounces from the mirror 304. Compared with the depth of field of the imaging system, the introduced optical path difference between these two spectral channels is negligible, therefore maintaining the images in focus for both colors.

Using the multicolor CUP system, a pulsed-laser-pumped fluorescence emission process was imaged. A fluorophore, Rhodamine 6G, in water solution was excited by a single 7 ps laser pulse at 532 nm. To capture the entire fluorescence decay, 50 billion frames per second was used by setting a shearing velocity of 0.66 mm/ns on the streak camera. Some representative temporal frames are shown in FIG. 5B. In addition, the time-lapse mean signal intensities were calculated within the dashed box in FIG. 5B for both the green and red channels (FIG. 5C). Based on the measured fluorescence decay, the fluorescence lifetime was found to be 3.8 ns, closely matching a previously reported value.

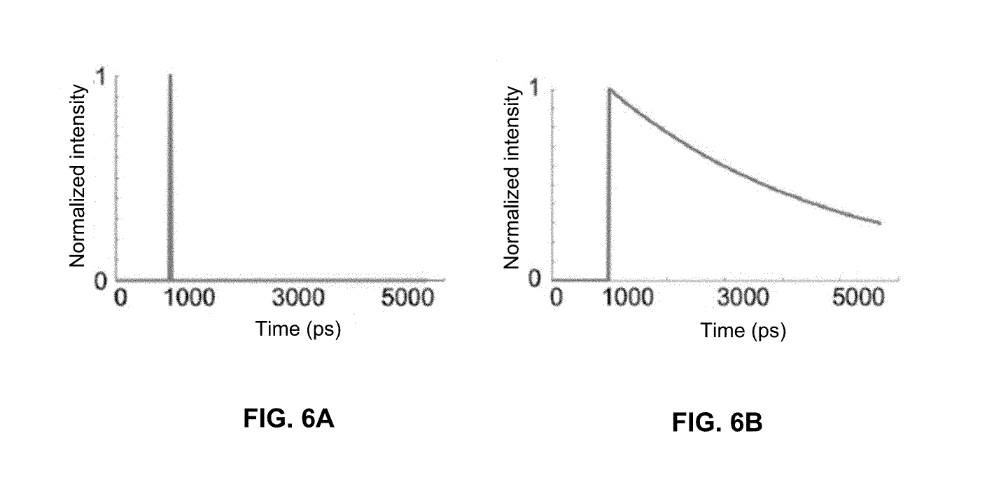

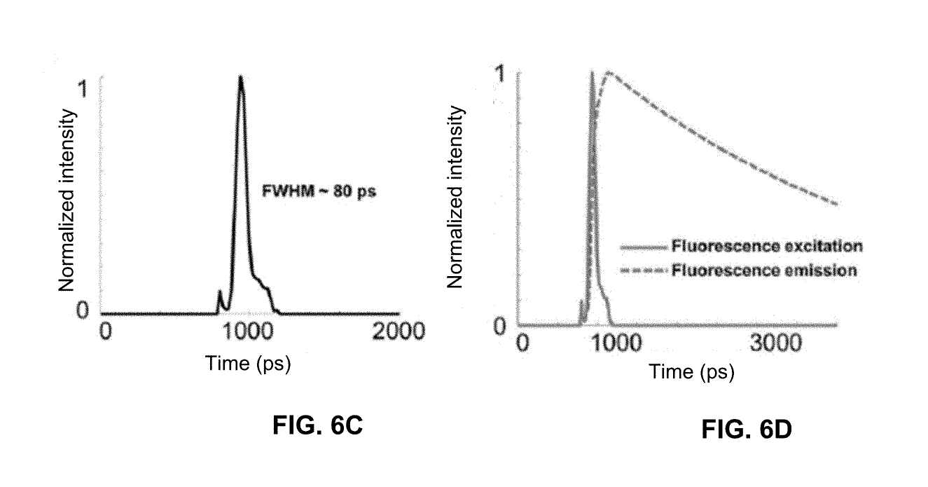

In theory, the time delay from the pump laser excitation to the fluorescence emission due to the molecular vibrational relaxation is ˜6 ps for Rhodamine 6G. However, results show that the fluorescence starts to decay ˜180 ps after the pump laser signal reaches its maximum. In the time domain, with 50 billion frames per second sampling, the laser pulse functions as an approximate impulse source while the onset of fluorescence acts as a decaying edge source. Blurring due to the temporal PSF stretches these two signals' maxima apart. This process was theoretically simulated by using the experimentally measured temporal PSF and the fitted fluorescence decay as the input. The time lag between these two events was found to be 200 ps, as shown in FIG. 6D, which is in good agreement with experimental observation.

A simulation of temporal responses of pulsed-laser-pumped fluorescence emissions was conducted. FIG. 6A shows an event function Bdescribing the pulsed laser fluorescence excitation. FIG. 6b shows an event function describing the fluorescence emission. FIG. 6c is a measured temporal point-spread-function (PSF), with a full width at half maximum of ˜80 ps. Due to reconstruction artefacts, the PSF has a side lobe and a shoulder extending over a range of 280 ps. FIG. 6d are simulated temporal responses of these two event functions after being convolved with the temporal PSF. The maxima of these two time-lapse signals are stretched by 200 ps.

### Example 5

### Simulation of Temporal Responses of Pulsed-Laser-Pumped Fluorescence Emission

The temporal response of pulsed-laser-pumped fluorescence emission was simulated in Matlab. The arrival of the pump laser pulse and the subsequent fluorescence emission are described by a Kronecker delta function (FIG. 6a) and an exponentially decaying edge function (FIG. 6b), respectively. For the Rhodamine 6G fluorophore, the molecular vibrational relaxation time was neglected and the arrival of the pump laser pulse and the onset of fluorescence emission were considered to be simultaneous. After pump laser excitation, the decay of the normalized fluorescence intensity, Î(t), is modelled as Î(t)=exp(−t/τ), where τ=3.8 ns. To simulate the temporal-PSF-induced blurring, an experimentally measured temporal PSF (Extended Data FIG. 1c) was convolved with these two event functions shown in FIGS. 6A and 6B. The results in FIG. 6D indicate that this process introduces an approximate 200 ps time delay between the signal maxima of these two events. Although the full width at half maximum of the main peak in the temporal PSF is only ˜80 ps, the reconstruction-induced side lobe and shoulder extend over a range of 280 ps, which temporally stretches the signal maxima of these two events apart.

### Example 6

### Depth Resolution of ToF-CUP 3D Imaging

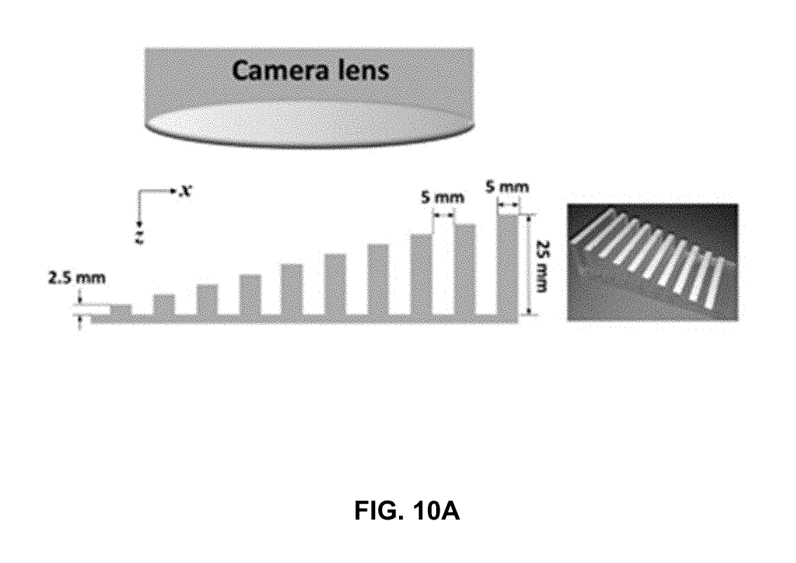

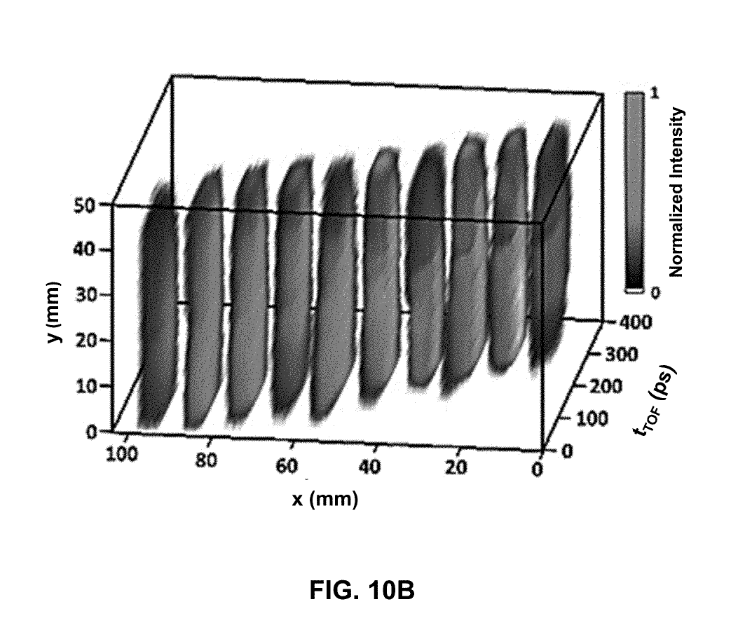

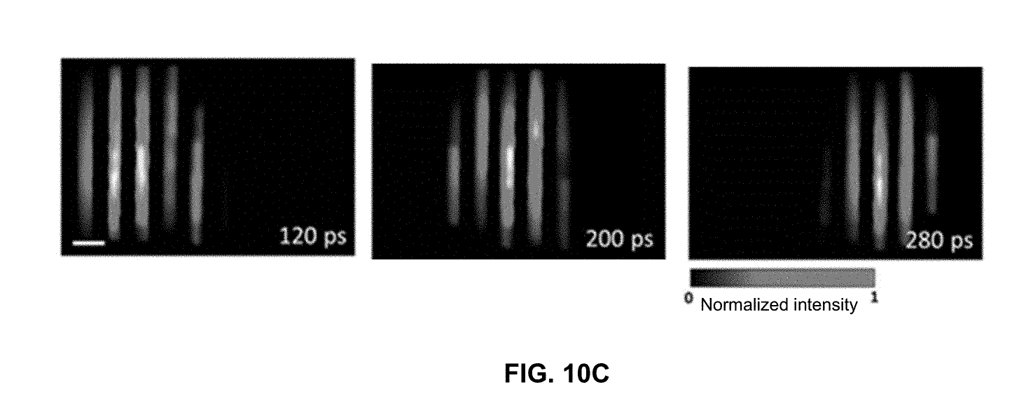

To quantify the ToF-CUP system's depth resolution, a 3D target with fins of varying heights (FIG. 10A) was imaged. This target (100 mm×50 mm along the x and y axes) was fabricated using a 3D printer (Form 1+, Formlabs). Along the x axis, each fin had a width of 5 mm, and the height of the fins ascended from 2.5 mm to 25 mm, in steps of 2.5 mm. The imaging system was placed perpendicular to the target and collected the backscattered photons from the surface. Image reconstruction retrieved the ToF 2D images (FIG. 10B). Three representative temporal frames at t_{TOF}=120, 200, and 280 ps are shown in FIG. 10C. In each frame, five fins are observed, indicating that the system's depth resolution is approximately 10 mm.

### Example 7

### ToF-CUP 3D Imaging of Static Objects

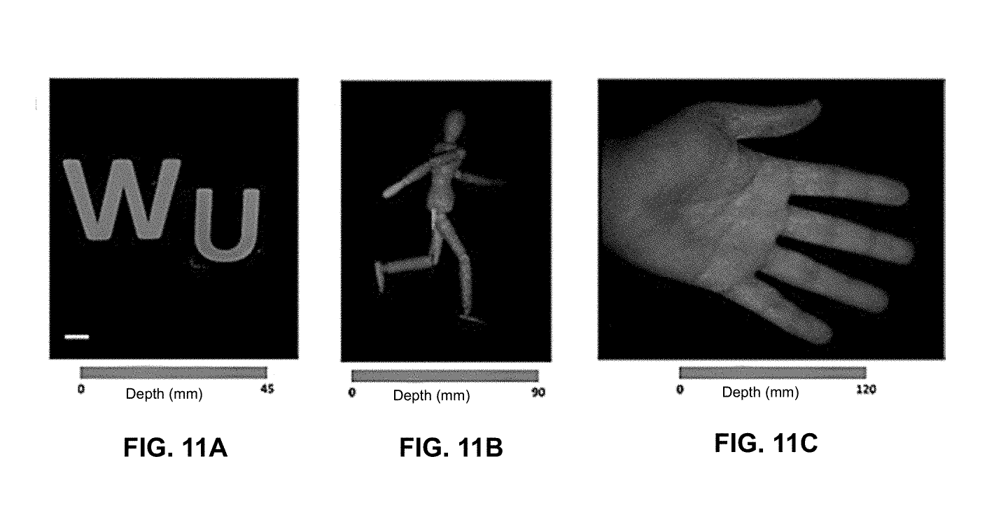

To demonstrate ToF-CUP's 3D imaging capability, static objects were imaged. Specifically, two letters, “W” and “U”, were placed with a depth separation of 40 mm. The streak camera acquired a spatially-encrypted, temporally-sheared image of this 3D target in a single snapshot. The reference camera also directly imaged the same 3D target without temporal shearing to acquire a reference. The ToF signal was converted into depth information as described herein above, and ToF-CUP reconstructed a 3D x, y, z image of the target. For each pixel in the x-y plane, we found the maximum intensity in the z axis and recorded that coordinate to build a depth map. We color-encoded this depth map and overlaid it with the reference image to produce a depth-encoded image (FIG. 11A). For this object, the depth distance between the two letters was measured to be ˜40 mm, which agreed with the true value. In addition, we imaged two additional static objects, a wooden mannequin and a human hand (FIGS. 11B and 11C). In both cases, the depth information of the object was obtained using ToF-CUP. It is worth noting that the lateral resolution of the reconstructed datacube was ˜0.1 line pairs per mm, and the reference images taken by the external CCD camera had a higher lateral resolution (˜0.8 line pairs per mm). Because the depth-encoded image was produced by overlaying the depth map with the reference image, it had a lateral resolution limited by the reconstructed datacube.

### Example 8

### Encryption of ToF-CUP 3D Images

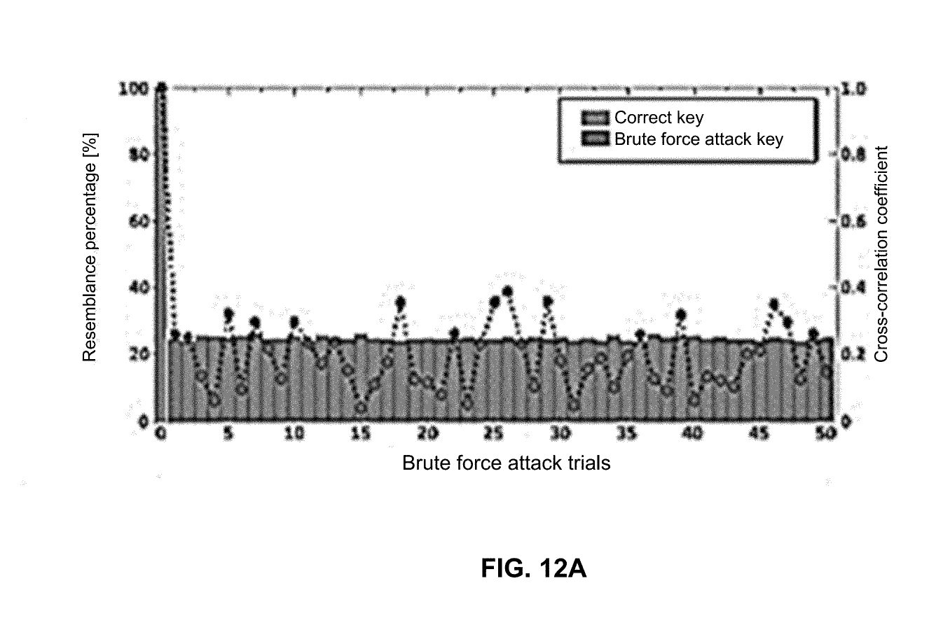

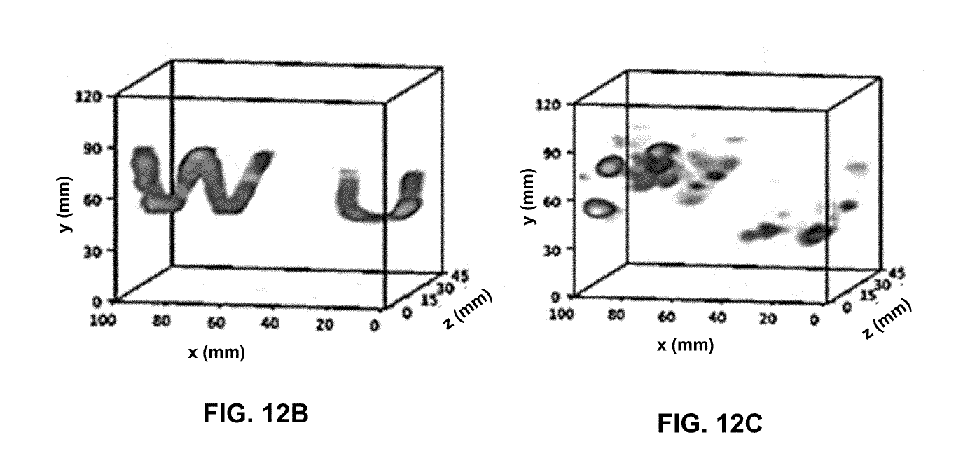

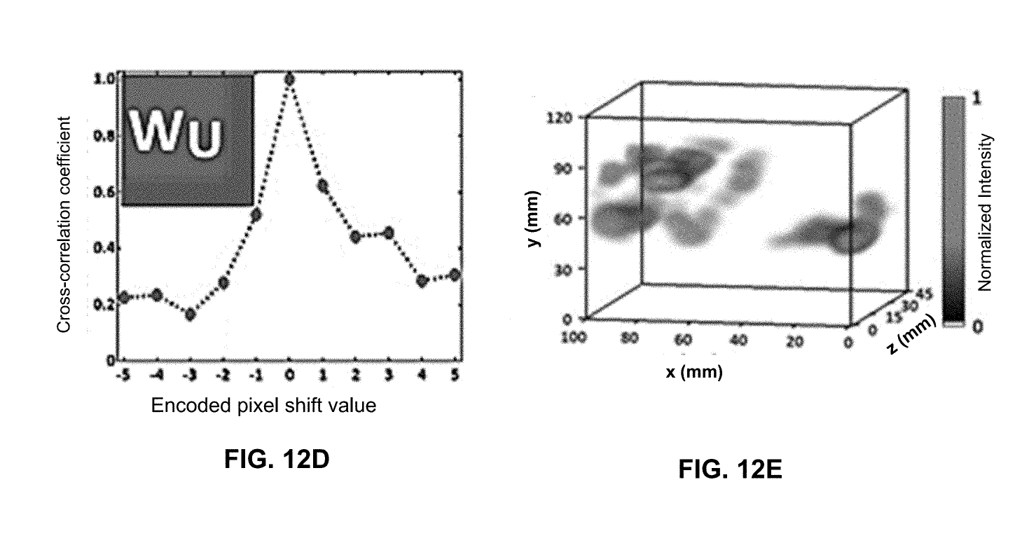

To verify the system's encryption capability, the image quality of the 3D datacubes reconstructed under two types of decryption attacks was compared to a reference image. The static 3D object “WU” was used in these tests. First, a brute force attack was simulated, which attempted to guess the decryption key without any prior information. Pseudo-random binary masks were generated as invalid decryption keys. For each invalid key, the percentage of resemblance to the correct key was calculated. After the reconstruction, the cross correlations between the 3D datacubes based on these invalid keys and the one based on the correct key were calculated to quantify the reconstructed image quality (FIG. 12A). Without the valid decryption key, the reconstructed image quality was largely degraded, as reflected in the decreased correlation coefficients. For direct comparison, the reconstructed 3D datacube of the “WU” target produced by the valid and invalid keys are shown (FIGS. 12B and 12C, respectively). With the correct decryption key, the reconstructed image resembled the object. The image reconstructed using the invalid decryption key, on the contrary, yielded no useful information. In each attack, the reconstruction using the invalid key failed to retrieve the depth information, which demonstrated that the ToF-CUP encryption method is resistant to brute force attacks.

In addition, the strength of encryption was assessed when part of the encryption key was known, but its position with respect to the encrypted image was unknown. To simulate this situation, a subarea (40×40 encoded pixels in the x and y axes) was selected from the full encryption key (50×50 encoded pixels in the x and y axes) as the decryption key (FIG. 12D). This decryption key was horizontally shifted by various numbers of the encoded pixels. For each shift, the reconstructed 3D datacube was compared with the correct reconstruction result to calculate the cross-correlation coefficient (FIG. 12D). The comparison showed that the reconstruction quality was sensitive to the relative position between the decryption key and the encrypted data (FIG. 12E), demonstrating that ToF-CUP encrypting can protect the information in the 3D datacube even when part of the encryption key is leaked. The reconstructed datacubes from invalid decryption keys contained randomly distributed artifacts, some of which may have high intensity. These artifacts may affect the cross-correlation calculation. However, as shown in FIGS. 12C and 12E, even with seemingly high cross-correlation coefficients, the reconstruction using invalid encryption keys did not resemble the original 3D object.

### Example 9

### ToF-CUP 3D Images of Moving Objects

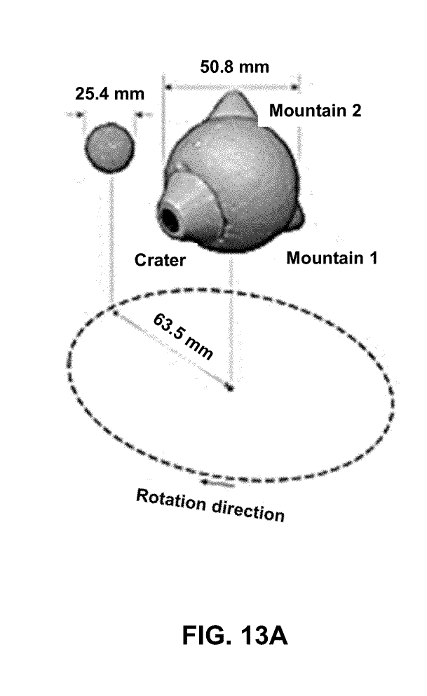

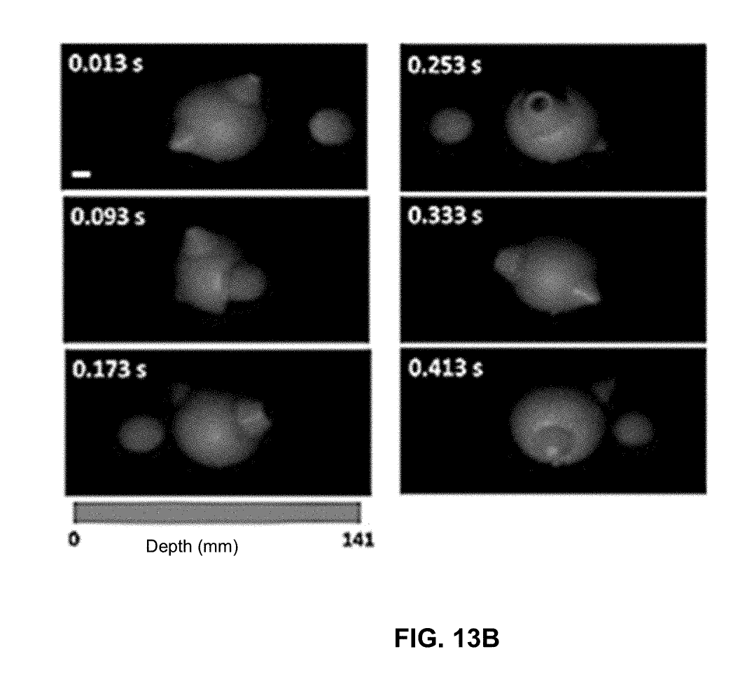

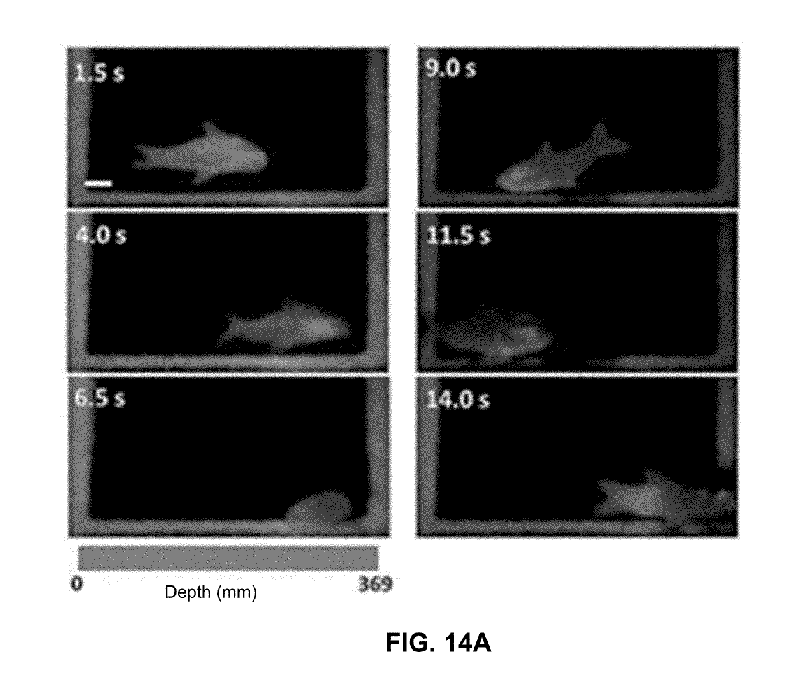

To demonstrate ToF-CUP's dynamic 3D imaging capability, a rotating object was imaged in real time (FIG. 13A). In the experiment, a foam ball with a diameter of 50.8 mm was rotated by a motorized stage at ˜150 revolutions per minute. Two “mountains” and a “crater” were added as features on this object. Another foam ball, 25.4 mm in diameter, was placed 63.5 mm from the larger foam ball and rotated concentrically at the same angular speed. The ToF-CUP camera captured the rotation of this two-ball system by sequentially acquiring images at 75 volumes per second. Once each image was reconstructed to a 3D x, y, z datacube, these datacubes formed a time-lapse 4D x, y, z, is datacube. FIG. 13B shows representative depth-encoded images at six different slow-time points, which revealed the relative depth positions of these two balls.

### Example 10

### ToF-CUP 3D Images of Live Organisms

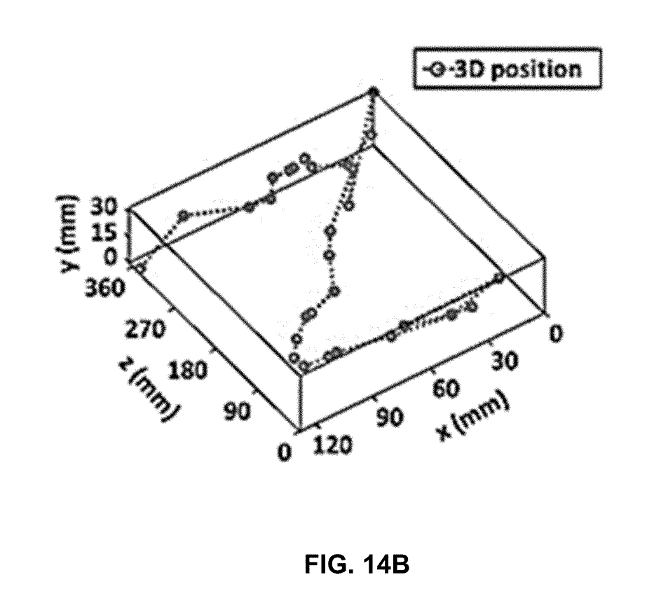

To apply ToF-CUP's dynamic 3D imaging capability to biological applications, a swimming comet goldfish (Carassius auratus) was imaged. The ToF-CUP camera acquired 3D images at two volumes per second to capture the fish's relatively slow movement over a sufficiently long time. FIG. 14A shows six representative depth-encoded images of the fish. By tracing the centroid of each reconstructed datacube, we demonstrated 3D spatial position tracking of the fish (FIG. 14B). In this representative example, the ToF-CUP camera revealed that the fish first stayed at the rear lower left corner and then moved toward the right, after which it started to move toward the front wall of the fish tank.

In these dynamic 3D imaging experiments, the external CCD camera was operated at a relatively long exposure time to tolerate relatively weak backscattered light. As a result, the movement of objects blurred the reference image. In contrast, because the exposure time of the streak camera is on the nanosecond level, the movement of the object did not noticeably affect the reconstructed datacube. Hence, the lateral and depth resolutions in the reconstructed images were not degraded.

### Example 11

### ToF-CUP 3D Images of Objects in Scattering Media

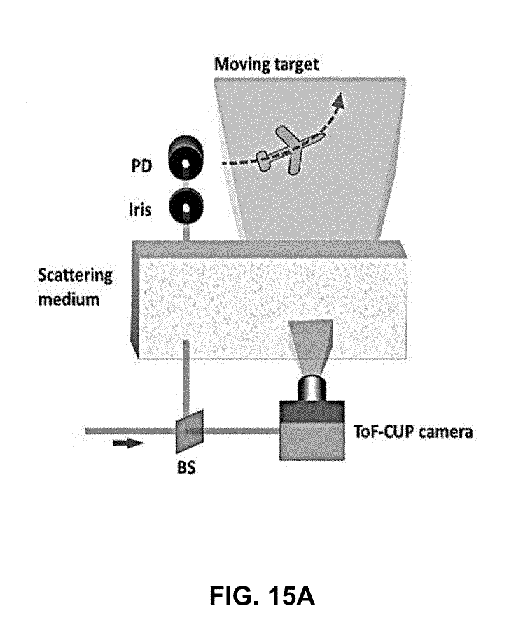

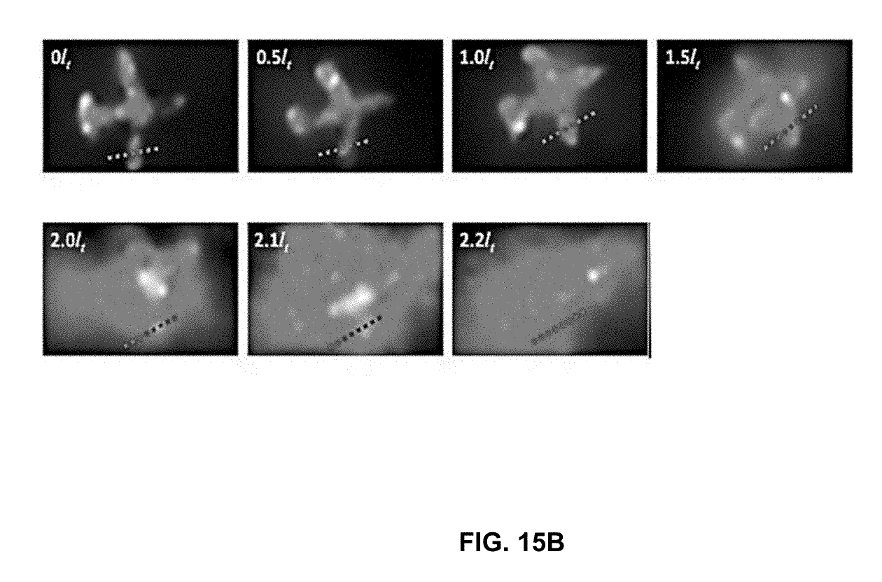

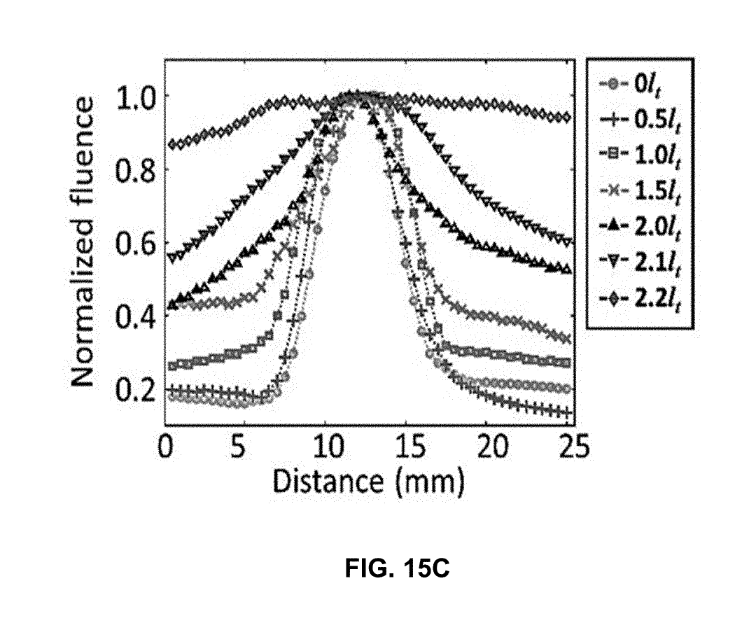

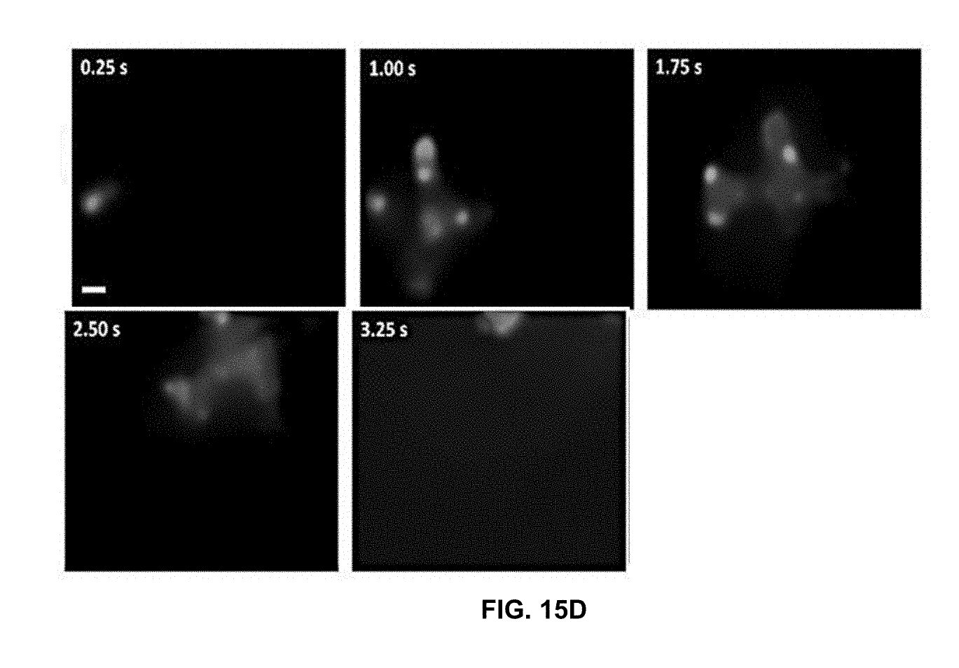

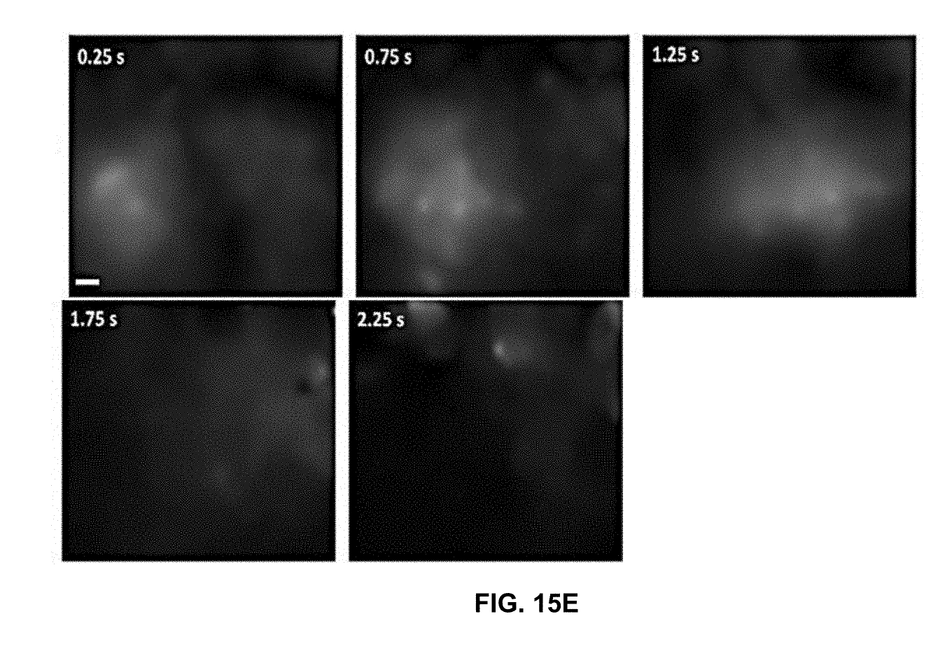

To explore ToF-CUP's imaging capability in a real-world environment, the ToF-CUP system was used to image an object moving behind a scattering medium that was composed by adding various concentrations of milk to water in a tank. The experimental setup is illustrated in FIG. 15A. Specifically, the incident laser beam was first de-expanded to ˜2 mm in diameter. A beam sampler reflected a small fraction of the energy of the beam toward the tank. After propagating through the scattering medium, the transmitted beam passed through an iris (˜2 mm in diameter). Then, the transmitted beam was measured by a photodiode detector to quantify the scattering level in the medium, which is presented as the equivalent scattering thickness in units of the mean free path (lₜ). The rest of the incident laser beam was sent through the beam sampler and reflected by a mirror to an engineered diffuser (see FIG. 9), which generated wide-field illumination of a moving airplane-model target behind the scattering medium. This manually operated airplane-model target moved in a curved trajectory illustrated in FIG. 15A.

The ToF-CUP camera imaged this moving object through the scattering medium with various scattering thicknesses. To quantitatively compare the image quality, we selected a representative reconstructed 3D x, y, z, image at a single slow-time point for each scattering thickness, and summed over the 3D image voxels along the z axis. The resultant projected images are shown in FIG. 15B. In addition, the intensity profile of a cross section of the airplane wing is plotted under these conditions in FIG. 15C. The image contrast decreased with increased scattering in the medium and finally vanishes when the scattering thickness reaches 2.2 lₜ. FIGS. 15D and 15E show representative images of this moving airplane target at five different slow-time points with two scattering thicknesses (1.0 lₜ in FIG. 15D and 2.1 lₜ in FIG. 15E), which record that the airplane-model target moved from the lower left to the upper right, as well as toward the ToF-CUP camera in the depth direction. Although scattering causes loss of contrast and features in the image, the depth can still be perceived. Due to the manual operation, the speed of the airplane-model target was slightly different in each experiment. As a result, the recorded movies with two scattering thicknesses (1.0 lₜ and 2.1 lₜ) have different lengths, and so have the selected representative images in FIGS. 15D and 15E.

The foregoing merely illustrates the principles of the invention. Various modifications and alterations to the described embodiments will be apparent to those skilled in the art in view of the teachings herein. It will thus be appreciated that those skilled in the art will be able to devise numerous systems, arrangements and methods which, although not explicitly shown or described herein, embody the principles of the invention and are thus within the spirit and scope of the present invention. From the above description and drawings, it will be understood by those of ordinary skill in the art that the particular embodiments shown and described are for purposes of illustrations only and are not intended to limit the scope of the present invention. References to details of particular embodiments are not intended to limit the scope of the invention.

1. A compressed-sensing ultrafast photography system to obtain a series of final recorded images of an object, the system comprising:
a spatial encoding module to receive a first series of object images and to produce a second series of spatially encoded images, each spatially encoded image of the second series comprising one object image of the first series superimposed with a pseudo-random binary spatial pattern; and
a temporal encoding module operatively coupled to the spatial encoding module, the temporal encoding module configured to receive an entire field of view of each spatially encoded image of the second series, to deflect each spatially encoded image by a temporal deflection distance proportional to time-of-arrival, and to record each deflected image as a third series of spatially/temporally encoded images, each spatially/temporally encoded image of the third series comprising an object image superimposed with a pseudo-random binary spatial pattern and deflected by the temporal deflection distance.

2. The system of claim 1, wherein the series of final recorded images are obtained with a frame rate of up to about 1 billion frames per second from a single event.

3. The system of claim 2, wherein the spatial encoding module comprises a digital micromirror device comprising an array of micromirrors, each micromirror configured to reflect or absorb a portion of the object image according to the pseudo-random binary pattern.

4. The system of claim 3, wherein the temporal encoding module comprises a streak camera with an entrance slit opened to receive an entire field of view of each spatially encoded image of the second series, wherein the temporal deflection distance is proportional to the time-of-arrival and a sweep voltage triggered within the streak camera and wherein the streak camera further includes a CCD to record the third series of spatially/temporally encoded images.

5. The system of claim 4, further comprising a spectral separation module operatively coupled to the spatial encoding module and the temporal encoding module, wherein the spectral separation module:
receives the second series of spatially encoded images from the spatial encoding module;
deflects a first spectral portion of each spatially encoded image comprising a first wavelength and a second spectral portion of each spatially encoded image comprising a second wavelength by a spectral deflection distance proportional to the first wavelength and the second wavelength, respectively; and
produces a fourth series of spatially/spectrally encoded images, each spatially/spectrally encoded image comprising an object image superimposed with a pseudo-random binary spatial pattern and with the first and second spectral portions deflected by corresponding spectral deflection distances, and wherein the spectral separation module comprises a dichroic filter mounted on a mirror at a tilt angle, wherein the first spectral portion of each spatially encoded image comprising the first wavelength reflects off of the dichroic filter at a first angle and the second spectral portion of each spatially encoded image comprising the second wavelength passes through the dichroic filter and reflects off of the mirror at a second angle comprising the combined first angle and tilt angle.

6. The system of claim 5, wherein the temporal encoding module is configured to receive an entire field of view of each spatially/spectrally encoded image of the fourth series, to deflect each spatially/spectrally encoded image of the fourth series by the temporal deflection distance, and to record each deflected image as a fifth series of spatially/spectrally/temporally encoded images, each spatially/spectrally/temporally encoded image of the fifth series comprising an object image superimposed with a pseudo-random binary spatial pattern, first and second spectral portions deflected by spectral deflection distances and deflected by the temporal deflection distance and wherein the spectral deflection distance is oriented perpendicular to the temporal deflection distance.

7. (canceled)

8. The system of claim 6, wherein the spectral separation module comprises a dichroic filter mounted on a mirror at a tilt angle, wherein the first spectral portion of each spatially encoded image comprising the first wavelength reflects off of the dichroic filter at a first angle and the second spectral portion of each spatially encoded image comprising the second wavelength passes through the dichroic filter and reflects off of the mirror at a second angle comprising the combined first angle and tilt angle.

9.-11. (canceled)

12. The system of claim 8, wherein the system further include an optical module to direct the first series of object images to the spatial encoding module and to direct the second series of spatially encoded images to the temporal encoding module, wherein the optical module comprises at least one of: a camera lens, a beam splitter, a tube lens, an objective lens, and a fiber optic.

13. (canceled)

14. The system of claim 12, wherein the optical module comprises the camera lens operatively coupled to the beam splitter, the tube lens operatively coupled to the beam splitter, and an objective operatively coupled to the tube lens, wherein:
the camera lens receives the first series of object images;
the objective is operatively coupled to the spatial encoding module to deliver the first series of object images; and
the beam splitter is operatively coupled to the temporal encoding module to deliver the second series of spatially encoded images via the objective and tube lens.

15. (canceled)

16. A method of obtaining a series of final recorded images of an object using a compressed-sensing ultrafast photography system at a rate of up to one billion frames per second, the method comprising:
collecting a first series of object images;
superimposing a pseudo-random binary spatial pattern onto each object image of the first series to produce a second series of spatially encoded images;
deflecting each spatially encoded image of the second series by a temporal deflection distance proportional to a time-of-arrival of each spatially encoded image;
recording each deflected spatially encoded image as a third series of spatially/temporally encoded images; and
reconstructing a fourth series of final object images by processing each spatially/temporally encoded image of the third series according to an image reconstruction algorithm.

17. The method of claim 16, wherein the image reconstruction algorithm comprises an inverse solution of:
E(x′,y′)=OS(x,y,t)
wherein:
E(x′, y′) comprises one spatially/temporally encoded image from the third series and (x′,y′) is a pixel location within the spatially/temporally encoded image;
S(x,y,t) comprises one final object image of the fourth series and (x,y,t) corresponds to a pixel location (x,y) within the final object image and at a time t; and
O is a linear operator comprising a linear model of obtaining the spatially/temporally encoded images as represented by:
O=ATC
wherein C is a spatial encoding operator representing the superimposing of the pseudo-random binary spatial pattern onto each object image, T is a temporal shearing operator representing the deflecting of each spatially encoded image of the second series by a temporal deflection distance; and A is a temporal integration operator representing the recording of each deflected spatially encoded image.

18. The method of claim 17, wherein the image construction algorithm is a two-step iterative shrinkage/thresholding algorithm comprising minimizing an objective function defined by:
$$\frac{1}{2} {‖ E - OS ‖}^{2} + λ Φ ( S )$$
wherein λ is the regularization parameter and Φ(S) is a regularization function comprising a total variation function Φ_{TV}(S) given by:
$${Φ}_{TV} ( S ) = {\sum }_{k = 1}^{{N}_{t}} {\sum }_{i = 1}^{{N}_{x} \times {N}_{y}} \sqrt{{( {Δ}_{i}^{h} {S}_{k} )}^{2} + {( {Δ}_{i}^{v} {S}_{k} )}^{2}} + {\sum }_{m = 1}^{{N}_{x}} {\sum }_{i = 1}^{{N}_{y} \times {N}_{t}} \sqrt{{( {Δ}_{i}^{h} {S}_{m} )}^{2} + {( {Δ}_{i}^{v} {S}_{m} )}^{2}} + {\sum }_{n = 1}^{{N}_{y}} {\sum }_{i = 1}^{{N}_{x} \times {N}_{t}} \sqrt{{( {Δ}_{i}^{h} {S}_{n} )}^{2} + {( {Δ}_{i}^{v} {S}_{n} )}^{2}} .$$
wherein: Nₓ and N_{y} are the number of pixels in the x and y directions of the final object image and Nₜ is the number of final object images.

19. The method of claim 18, wherein the pseudo-random binary spatial pattern is superimposed onto each object image of the first series using a digital micromirror device and wherein each spatially encoded image of the second series is deflected by a temporal deflection distance proportional to a time-of-arrival of each spatially encoded image using a streak camera with an entrance slit opened to receive an entire field of view of each spatially encoded image of the second series.

20. (canceled)

21. The method of claim 19, wherein the operator matrix O is obtained by:
recording a background image of the pseudo-random binary spatial pattern using uniform illumination in place of the object; and
constructing each successive time layer of the operator matrix by shifting the background image by a temporal distance corresponding to one time step.

22. The method of claim 21, further comprising:
deflecting a first spectral portion of each spatially encoded image comprising a first wavelength and a second spectral portion of each spatially encoded image comprising a second wavelength by a spectral deflection distance proportional to the first wavelength and the second wavelength, respectively to produce a fifth series of spectrally/spatially encoded images;
deflecting each spectrally/spatially encoded image of the fifth series by a temporal deflection distance proportional to a time-of-arrival of each spectrally/spatially encoded image;
recording each deflected spectrally/spatially encoded image as a sixth series of spectrally/spatially/temporally encoded images; and
reconstructing a seventh series of final object images by processing each spectrally/spatially/temporally encoded image of the sixth series according to the image reconstruction algorithm.

23. (canceled)

24. The system of claim 19, further comprising:
an illumination source comprising a pulsed laser operatively coupled to the temporal encoding module, wherein the illumination source delivers a laser pulse to illuminate the object and records a pulse delivery time, wherein an elapsed time between the pulse delivery time and the time of arrival is the round-trip time of flight; and
a reference camera to record a 2D reference image of the object, wherein the reference image is used as an intensity mask to enhance 3D image quality.

25.-28. (canceled)

29. The system of claim 24, wherein the optical module further direct the laser pulse to the object.

30.-32. (canceled)

33. The method of claim 19, wherein collecting the first series of object images further comprises
illuminating the object with a laser pulse prior to
collecting the first series of object images.

34. The method of claim 33, wherein the image reconstruction algorithm comprises a time of flight 3D image reconstruction algorithm, comprising an inverse solution of:
E(m,n)=TSCPR(x,y,z)
wherein:
E(m,n) comprises one spatially/temporally encoded image from the third series and (m,n) is a pixel location within the spatially/temporally encoded image;
R(x,y,t) comprises the 3D light intensity reflectivity of the object;
wherein P is a linear operator representing light illumination and backscattering, C is a spatial encoding operator representing the superimposing of the pseudo-random binary spatial pattern onto each object image, S is a spatiotemporal integration operator representing the recording of each deflected spatially encoded image, and T is a temporal shearing operator representing the deflecting of each spatially encoded image of the second series by a temporal deflection distance.

35. The method of claim 34, wherein the time of flight 3D image reconstruction algorithm is a two-step iterative shrinkage/thresholding algorithm comprising minimizing an objective function defined by:
arg min [1/2∥E−TSCPR∥²+λΦ_{TV}(PR)]
wherein λ is a regularization parameter and Φ_TV is the total-variation (TV) regularizer that encourages sparsity in the gradient domain during reconstruction.

36.-37. (canceled)
